(19) United States
(12) Patent Application Publication
(10) Pub. No.: US 2025/0273528 A1
(43) Pub. Date: Aug. 28, 2025

(54) DEVICE PACKAGE HAVING A CONTACTLESS SENSOR AND PROCESS OF IMPLEMENTING THE SAME

(71) Applicant: WOLFSPEED, INC., Durham, NC (US)

(72) Inventors: Mohammad Hazzaz MAHMUD, Fayetteville, AR (US); Ahmad AL-HMOUD, Durham, NC (US); Jukkrit NOPPAKUNKAJORN, Durham, NC (US); Marcelo SCHUPBACH, Fayetteville, AR (US); Sayan SEAL, Fayetteville, AR (US)

(21) Appl. No.: 18/586,142

(22) Filed: Feb. 23, 2024

(51) Int. Cl. H01L 23/34

(52) U.S. Cl. CPC H01L 23/34

(57) ABSTRACT

A device package includes an assembly that includes an assembly top surface; signal contacts arranged in and/or on the assembly; power contacts arranged in and/or on the assembly; at least one power device; at least one sensor receptacle; and at least one sensor arranged in the at least one sensor receptacle.

### BACKGROUND OF THE DISCLOSURE

Typical semiconductor device products are compact in size, designed for high reliability, and intended for high volume manufacturing. Typically, to keep a small form factor of the product, sensors, such as internal temperature sensors, are not installed. In other typical semiconductor device products, a sensor is located in an adjoining structure. Such a sensor arrangement enables some form of general measurement that relates only to the adjoining structure. For example, in typical semiconductor device products, a temperature sensor is attached to and contacts an adjoining power substrate structure. Such a temperature sensor arrangement enables some form of general temperature measurement of the adjoining power substrate.

Accordingly, a device package is needed to provide a more accurate and/or a more direct measurement of a device property. Moreover, a process of implementing a device package is needed to provide a more accurate and/or a more direct measurement of a device property.

### SUMMARY OF THE DISCLOSURE

In one aspect, a device package includes an assembly and the assembly comprises an assembly top surface. The device package in addition includes signal contacts arranged in and/or on the assembly. The package moreover includes power contacts arranged in and/or on the assembly. The package also includes at least one power device. The package further includes at least one sensor receptacle. The package in addition includes at least one sensor arranged in the at least one sensor receptacle. The package moreover includes where the at least one sensor receptacle is arranged in and/or on the assembly top surface.

In one aspect, a device package includes an assembly and the assembly comprises an assembly top surface. The device package in addition includes signal contacts arranged in and/or on the assembly. The package moreover includes power contacts arranged in and/or on the assembly. The package also includes at least one power device. The package further includes at least one sensor receptacle. The package in addition includes at least one sensor arranged in the at least one sensor receptacle. The package moreover includes where the at least one sensor is arranged on an axis perpendicular to a top surface of the at least one power device.

In one aspect, a device package includes an assembly and the assembly comprises an assembly top surface. The device package in addition includes signal contacts arranged in and/or on the assembly. The package moreover includes power contacts arranged in and/or on the assembly. The package also includes at least one power device. The package further includes at least one sensor receptacle. The package in addition includes at least one sensor arranged in the at least one sensor receptacle. The package moreover includes where the at least one sensor receptacle and the at least one sensor are arranged above the at least one power device.

In one aspect, a process includes providing an assembly having an assembly top surface. The process in addition includes arranging signal contacts in and/or on the assembly. The process moreover includes arranging power contacts in and/or on the assembly. The process also includes providing at least one power device. The process further includes providing at least one sensor receptacle. The process in addition includes arranging at least one sensor in the at least one sensor receptacle. The process moreover includes arranging the at least one sensor receptacle in and/or on the assembly top surface.

In one aspect, a process includes providing an assembly having an assembly top surface. The process in addition includes arranging signal contacts in and/or on the assembly. The process moreover includes arranging power contacts in and/or on the assembly. The process also includes providing at least one power device. The process further includes providing at least one sensor receptacle. The process in addition includes arranging at least one sensor in the at least one sensor receptacle. The process moreover includes arranging the at least one sensor on an axis perpendicular to a top surface of the at least one power device.

In one aspect, a process includes providing an assembly having an assembly top surface. The process in addition includes arranging signal contacts in and/or on the assembly. The process moreover includes arranging power contacts in and/or on the assembly. The process also includes providing at least one power device. The process further includes providing at least one sensor receptacle. The process in addition includes arranging at least one sensor in the at least one sensor receptacle. The process moreover includes arranging the at least one sensor receptacle and the at least one sensor above the at least one power device.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a top side perspective view of a device package according to aspects of the disclosure.

FIG. 2 illustrates a top side perspective view of another device package according to aspects of the disclosure.

FIG. 3 illustrates a top side perspective view of another device package according to aspects of the disclosure.

FIG. 4 illustrates a top side perspective view of another device package according to aspects of the disclosure.

FIG. 5 illustrates a partial top side perspective view of the device packages according to aspects of the disclosure.

FIG. 6 illustrates a cross-sectional front view of the device package according to FIG. 1.

FIG. 7 illustrates a cross-sectional side view of the device package according to FIG. 1.

FIG. 8 illustrates a cross-sectional front view of the device package according to aspects of the disclosure.

FIG. 9 illustrates a cross-sectional front view of the device package according to aspects of the disclosure.

FIG. 10 illustrates a further cross-sectional front view of the device package according to FIG. 1.

FIG. 11 illustrates a further cross-sectional side view of the device package according to FIG. 1.

FIG. 12 illustrates a further cross-sectional front view of the device package according to FIG. 1.

FIG. 13 illustrates a further cross-sectional side view of the device package according to FIG. 1.

FIG. 14 illustrates a thermal diagram of the device package implementing the at least one sensor receptacle and the at least one temperature sensor according to aspects of the disclosure.

FIG. 15 illustrates a temperature time response comparison graph of different temperature sensor implementations in an exemplary implementation of the device package.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

In current semiconductor device products, a temperature sensor is attached to and contacts an adjoining power substrate structure. Such a temperature sensor arrangement enables some form of general temperature measurement of the adjoining power substrate. However, due to an internal construction of the product, the temperature sensor location, arrangement, and/or configuration provides inaccurate readings. In this regard, the temperature sensor only provides estimates, all while contributing to a larger more complex and/or more expensive product. Thus, users cannot directly and/or accurately measure semiconductor device temperature in such typical semiconductor device products.

The disclosed device and process may implement a relatively small trench and/or trenches positioned over one or more of the internal devices, while keeping only minimal amount of material between a device and a bottom of the trench. The disclosed device and process may enable a very precise device junction temperature reading by different types of sensors, including infrared (IR) thermopile sensors, thermocouples, negative temperature coefficient (NTC) sensors, positive temperature coefficient (PTC) sensors, and/or the like. In addition to a single trench option, multiple trenches can be added on the device in multiple locations to measure very accurate device junction temperatures.

For example, the disclosed device and process may implement a relatively small trench and/or trenches in a molding of an overmolded module, positioned over one or more of the internal devices, while keeping only minimal amount of molding compound between the device and the bottom of the trench. The disclosed device and process may enable a very precise device junction temperature reading by the temperature sensors. In addition to a single molding trench option, multiple trenches can be added on the modules in multiple locations to measure very accurate device junction temperatures.

The disclosed device and process may provide an externally accessible spot configured and/or designed to be in a close proximity to a device junction. Accordingly, the disclosed device and process may provide a considerably more accurate and faster sensing implementation then an internal temperature sensor inside the product, such as module, while allowing to manufacture of products, such as modules, without an internal temperature sensor, enabling smaller, more cost effective, and more optimized modules. The disclosed device and process may allow users more design flexibility on a system level, and possibly enabling safer and more noise immune temperature readings by using non-contact sensors. Further, the disclosed device and process may be implemented in products, such as a case module, by adding a non-reflective gel for isolation.

The disclosed device and process may implement a thermally optimized feature of a product, such as module, which may enable optimized external temperature sensing. The disclosed device and process may provide a built-in and user-friendly external location feature of monitoring the internal temperature of the device externally, with sensor performance superior to internally positioned sensors.

For example, the disclosed process and device may be implemented by adding a “valley” feature to product, such as a power module molding surface. In this regard, an external sensor may be implemented to detect an external temperature very close to an internal device temperature.

The disclosed device and process may be implemented in a molding trench and/or trenches on a surface of the molding down to as close to the device as possible, leaving the minimum amount of molding compound. The trench diameter, depth, and position may be dependent on the product structure, for example a module structure. However, the disclosed device and process may be applied to any overmolded device, case modules, and/or the like. For example, the disclosed device and process may include multiple implementations.

In particular aspects, the disclosed device and process may implement a round molding trench, multiple molding trenches, a square trench, a rectangular slot, and/or the like. Additionally, the disclosed device and process can be added to an existing product, such as a case module, a discrete device, and/or the like.

In particular aspects, the disclosed device and process may implement one or more trenches on a plastic implementation, a molding implementation, and/or the like in different types of power modules, discrete packages, and/or the like.

In aspects, the disclosed device and process may provide precise external measurement of a device temperature in a product, such as an overmolded module.

Implementing the disclosed device and process adds no or minimal additional bill of material (BOM) cost as it will be part of the mold shape. Further, the disclosed device and process may allow more optimized, more cost effective, and smaller products, such as modules, since it will no longer need to implement an internal temperature sensor.

The disclosed device and process may be implemented in various products such as an overmolded platform, case modules, discrete devices, and/or the like. In aspects, the disclosed temperature sensor may be implemented in any type of device including a discrete semiconductor device, a discrete semiconductor device package, a module, a semiconductor module, a power module, a power package, a device package, a case module, an overmolded module, a semiconductor package, and/or the like.

Moreover, the disclosed temperature sensor may be used in any type of device implementing Silicon devices, silicon carbide (SiC) devices, gallium nitride (GaN) devices, metal-oxide-semiconductor field-effect transistor (MOSFET) devices, insulated-gate bipolar transistor (IGBT) devices.

Accordingly, the disclosed device and process solves the limitation due to absence of internal temperature sensors, by adding a feature to monitor internal junction temperature externally. Moreover, the disclosed device and process solves the limitations of current temperature sensors, by adding a feature to monitor internal junction temperature externally.

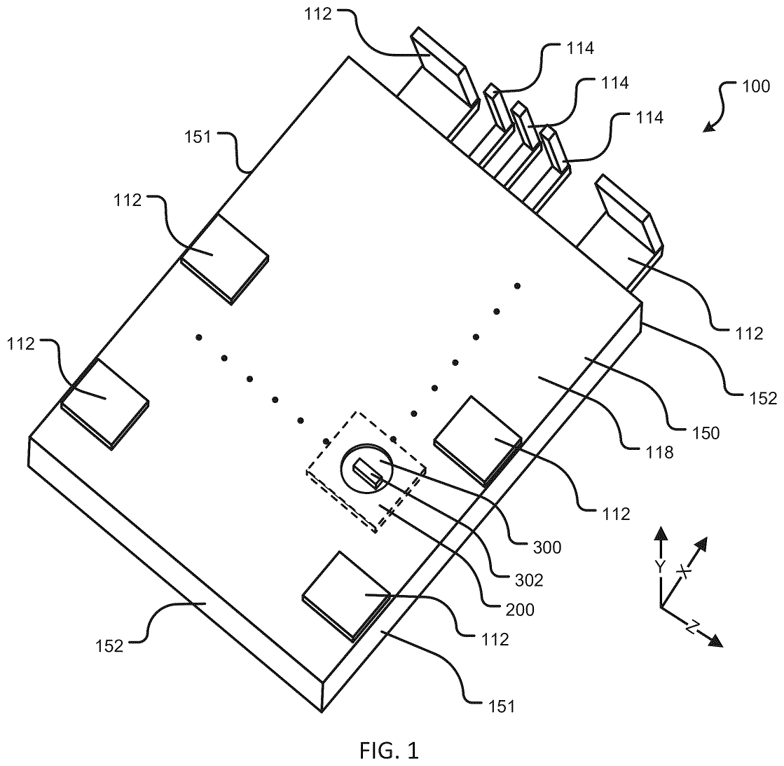

FIG. 1 illustrates a top side perspective view of a device package according to aspects of the disclosure.

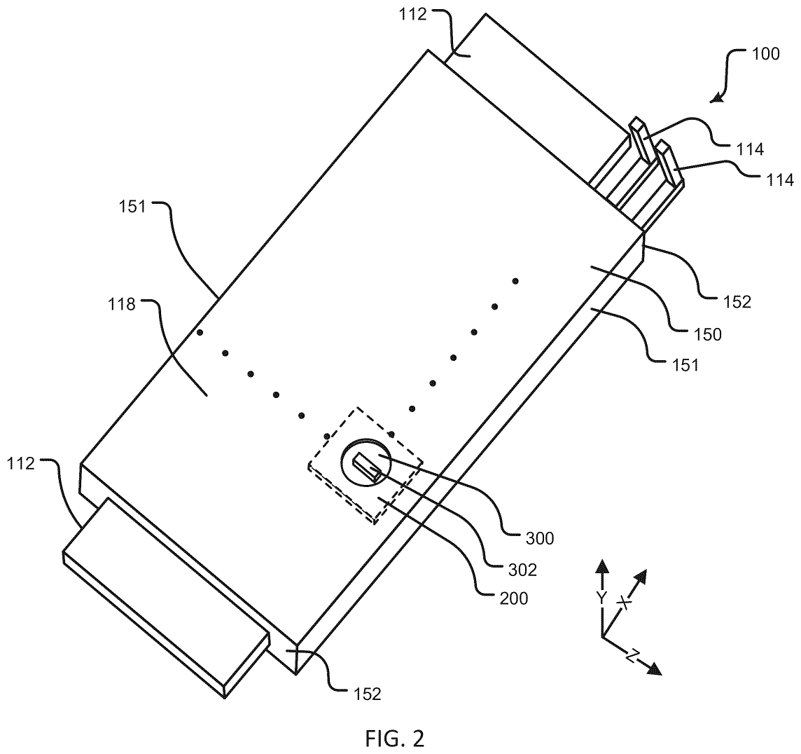

FIG. 2 illustrates a top side perspective view of another device package according to aspects of the disclosure.

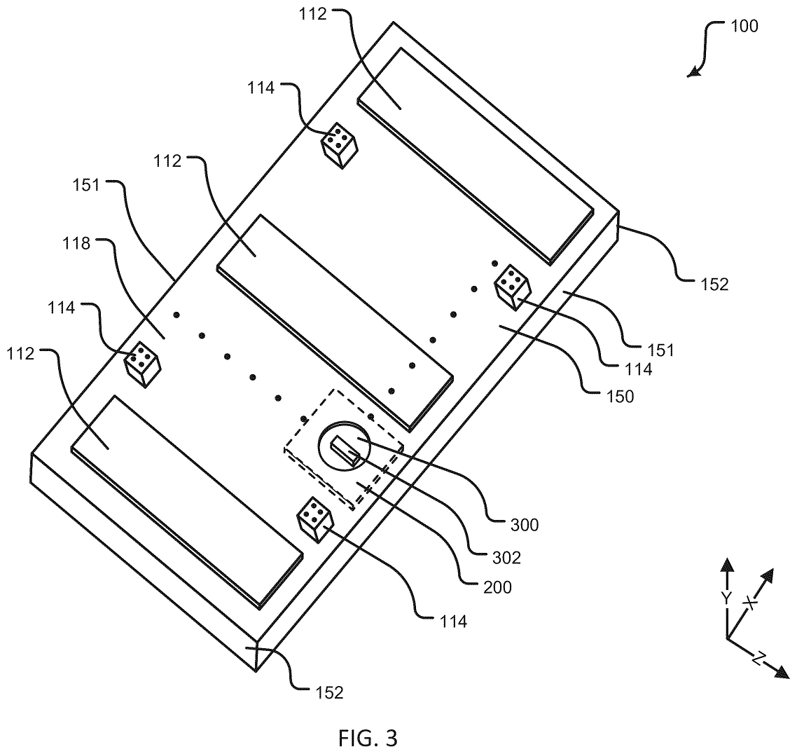

FIG. 3 illustrates a top side perspective view of another device package according to aspects of the disclosure.

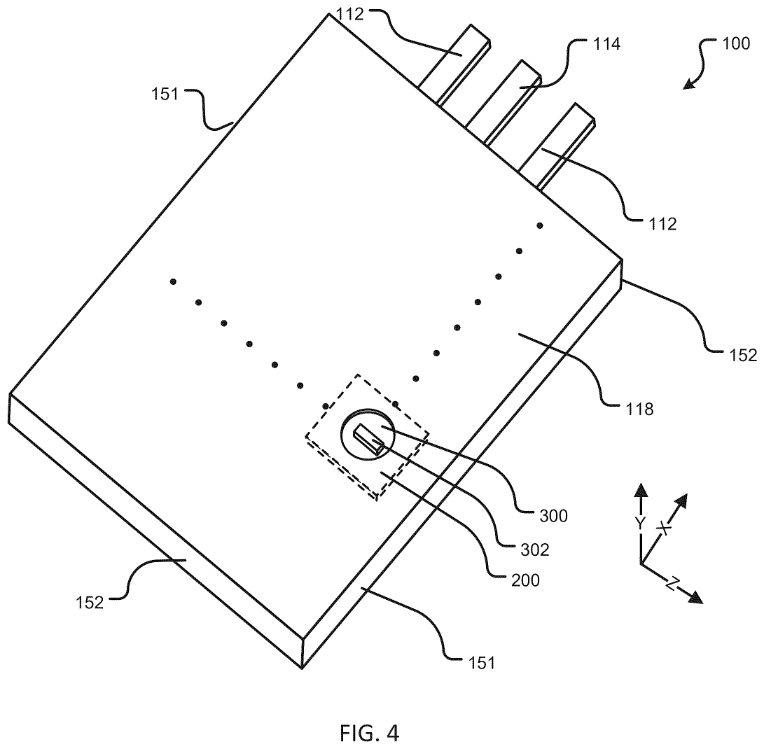

FIG. 4 illustrates a top side perspective view of another device package according to aspects of the disclosure.

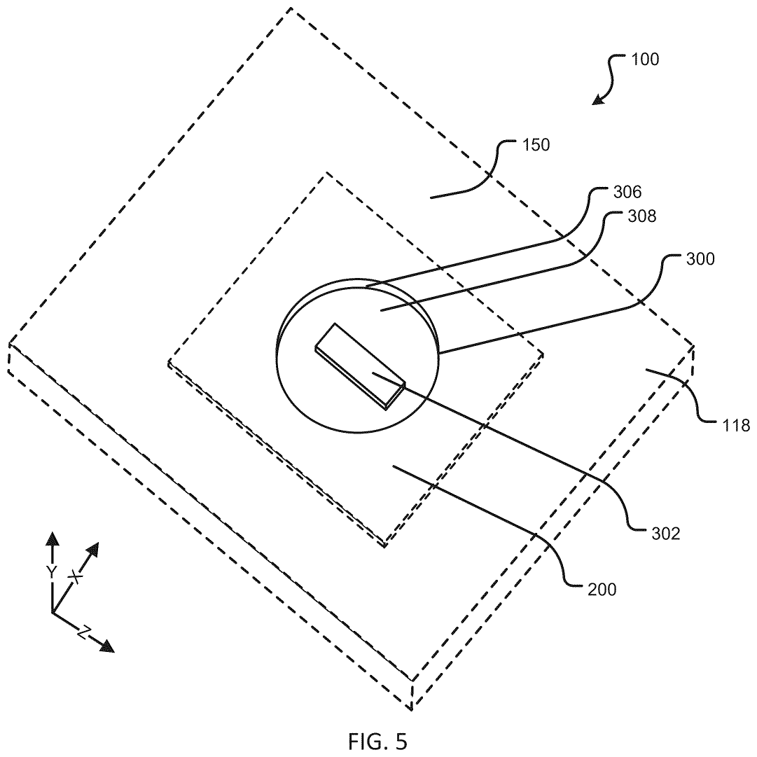

FIG. 5 illustrates a partial top side perspective view of the device packages according to aspects of the disclosure.

With reference to FIG. 1, a device package 100 may include an assembly 118, signal contacts 114, power contacts 112, and/or the like. In aspects, the device package 100 may implement and/or may be configured with any number of the signal contacts 114. In aspects, the device package 100 may implement and/or may be configured with any number of the power contacts 112. Moreover, the device package 100 may be configured with any arrangement and/or configuration of the signal contacts 114 and the power contacts 112.

Additionally, the device package 100 may include at least one power device 200, at least one sensor receptacle 300, and at least one sensor 302. In aspects, the at least one sensor 302 may be arranged in the at least one sensor receptacle 300. Moreover, the at least one sensor 302 and/or the at least one sensor receptacle 300 may be configured and arranged to accurately sense a property of the at least one power device 200. In aspects, the at least one sensor 302 and/or the at least one sensor receptacle 300 may be configured and arranged to accurately obtain a temperature of the at least one power device 200.

In aspects, the at least one sensor 302 may be configured to measure any type of property of one or more components of the device package 100 and/or the at least one power device 200 including temperature, current, voltage, pressure, vibration, humidity, magnetic field, strain, force, pressure, and/or the like. In aspects, the at least one sensor 302 may be configured to be any type of sensor. In aspects, the at least one sensor 302 may be a temperature sensor, a current sensor, a voltage sensor, a pressure sensor, a vibration sensor, a humidity sensor, a Hall effect sensor, a magnetic sensor, a strain sensor, a force sensor, a pressure sensor, and/or the like.

In aspects, the at least one sensor 302 may be configured as a contactless sensor. In aspects, the at least one sensor 302 may be configured to directly measure a property of a component of the device package 100 without contacting the component of the device package 100. In aspects, the at least one sensor 302 may be configured to directly measure a property of the at least one power device 200 without contacting the at least one power device 200.

In particular aspects, the device package 100 may implement the at least one sensor 302 as a temperature sensor. In this regard, the disclosure provides exemplary implementations of the at least one sensor 302 as a temperature sensor. However, the device package 100 may implement the at least one sensor 302 with other types of sensors as described herein.

As illustrated, the at least one power device 200 is illustrated with dashed lines as the at least one power device 200 may be arranged within the assembly 118 of the device package 100 and accordingly may not otherwise be externally visible. Further, as noted by the dotted lines, there may be any number of the at least one power device 200, the at least one sensor receptacle 300, and the at least one sensor 302.

In aspects, the device package 100 may be configured with and implement a plurality of the at least one power device 200 that may be arranged to extend along the z-axis or lateral axis. In aspects, the device package 100 may be configured with and implement a plurality of the at least one power device 200 that may be arranged to extend along the X-axis or longitudinal axis between the power contacts 112. In aspects, the device package 100 may be configured with and implement a plurality of the at least one power device 200 that may be arranged to extend along the z-axis or lateral axis; and the device package 100 may be configured with and implement a plurality of the at least one power device 200 that may be arranged to extend along the X-axis or longitudinal axis between the power contacts 112.

Further, any number of the at least one power device 200 may include the at least one sensor receptacle 300 and the at least one sensor 302; and/or any number of the at least one power device 200 may not include the at least one sensor receptacle 300 and the at least one sensor 302. In aspects, only one implementation of the at least one power device 200 may include the at least one sensor receptacle 300 and the at least one sensor 302. In aspects, multiple implementations the at least one power device 200 may include an implementation of the at least one sensor receptacle 300 and the at least one sensor 302. In aspects, all implementations of the at least one power device 200 may include implementations of the at least one sensor receptacle 300 and the at least one sensor 302.

In aspects, the device package 100 may be implemented as a power package, a semiconductor package, a power semiconductor package, an overmolded package, a module, a power module, a power semiconductor module, a power device module, an overmolded module, a case module, a case power module, a case power semiconductor module, a case power device module, a discrete device, a discrete power device, an overmolded discrete device, and/or the like. For example, the FIG. 4 implementation of the device package 100 is illustrated as being implemented as a discrete device.

Additionally, the assembly 118 may include an assembly top surface 150, assembly first sides 151, and assembly second sides 152. In aspects, the assembly first sides 151 may be straight, inclined, irregular, curved, and/or the like. In aspects, the assembly second sides 152 may be straight, inclined, irregular, curved, and/or the like.

In aspects, the assembly first sides 151 may extend along the X-axis or longitudinal axis. In aspects, the assembly second sides 152 may extend along the z-axis or lateral axis. In aspects, the assembly top surface 150 may connect to the assembly first sides 151 and the assembly second sides 152. In aspects, respective ends of the assembly first sides 151 and the assembly second sides 152 may be connected, directly connected, connected by intervening surfaces, and/or the like.

With reference to FIG. 5, the at least one sensor receptacle 300 may be arranged in the assembly top surface 150. In other aspects, the at least one sensor receptacle 300 may be arranged in the assembly first sides 151, the assembly second sides 152, elsewhere in the assembly 118, and/or the like. In aspects, the at least one sensor receptacle 300 may be a trench, a divot, a valley, a cavity, a channel, a tunnel, a groove, a pocket, an aperture, a hole, a location, a holder, an arrangement, and/or the like. As illustrated in FIG. 5, the at least one sensor receptacle 300 may have a circular shaped configuration. In other aspects, the at least one sensor receptacle 300 may have a square shape configuration, a rectangular shape configuration, a polygonal shape configuration, an irregular shape configuration, a regular shape configuration, and/or the like.

In aspects, the at least one sensor receptacle 300 may be configured, arranged, formed, and/or the like during formation of the assembly 118. For example, the assembly 118 may be a molded structure and the at least one sensor receptacle 300 may be formed by molding during a molding of the assembly 118. In these aspects, the at least one sensor receptacle 300 may be a molded structure and/or a molded sensor receptacle.

In other aspects, the at least one sensor receptacle 300 may be configured, arranged, formed, and/or the like after formation of the assembly 118. For example, the at least one sensor receptacle 300 may be machined into a surface thereof. In these aspects, the at least one sensor receptacle 300 may be a machined structure and/or a machined sensor receptacle.

In aspects, the at least one sensor 302 may be configured as an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, a thermistor, and/or the like. In aspects, the at least one sensor 302 may be an external sensor. In this regard, the at least one sensor 302 may be external to the assembly 118 and/or not on any structure of the device package 100 within the assembly 118. In aspects, the at least one sensor 302 is not arranged on a component within the assembly 118. In aspects, the at least one sensor 302 may be calibrated for any temperature offset. In particular, the at least one sensor 302 may be calibrated for any temperature offset of the at least one sensor 302 caused by a construction and location of the at least one sensor receptacle 300 and/or the at least one sensor 302 within the device package 100. In aspects, the at least one sensor 302 may be self calibrated for any temperature offset.

In aspects, the at least one sensor 302 may be configured to directly measure a temperature of the at least one power device 200, directly measure a junction temperature of the at least one power device 200, and/or the like. In aspects, the at least one sensor 302 may be configured as a contactless sensor. In aspects, the at least one sensor 302 may be configured to directly measure a temperature of the at least one power device 200, directly measure a junction temperature of the at least one power device 200, and/or the like without contacting the at least one power device 200.

In aspects, the device package 100 may be configured to arrange the at least one sensor 302 in a middle section or middle area of the at least one power device 200. Further, the at least one sensor receptacle 300 and/or the at least one sensor 302 may be arranged directly above the at least one power device 200. In aspects, the at least one sensor 302 may be arranged directly above the at least one power device 200 and/or the like along the y-axis or vertical axis (vertical relative to the orientation of the device package 100 as illustrated).

In aspects, the at least one sensor 302 may be arranged directly above the at least one power device 200 with a portion of the assembly 118 therebetween. In aspects, the at least one sensor 302 may be arranged directly above the at least one power device 200 with a minimal portion of the assembly 118 therebetween.

Moreover, the at least one sensor 302 may be arranged in the at least one sensor receptacle 300. In aspects, the at least one sensor 302 may be arranged such that there is a limited distance between the at least one sensor 302 and the at least one power device 200. In aspects, the at least one sensor 302 may be arranged such that there is a minimal distance between the at least one sensor 302 and the at least one power device 200.

In aspects, the at least one sensor 302 may be arranged such that there is a limited portion of the assembly 118 between the at least one sensor 302 and the at least one power device 200. In aspects, the at least one sensor 302 may be arranged such that there is a minimal portion of the assembly 118 between the at least one sensor 302 and the at least one power device 200.

In aspects, the at least one sensor 302 may be arranged 1 mm-10 mm into the assembly 118, and/or below the assembly top surface 150. In aspects, the at least one sensor 302 may be located 1 mm-2 mm, 2 mm-3 mm, 3 mm-4 mm, 4 mm-5 mm, 5 mm-6 mm, 6 mm-7 mm, 7 mm-8 mm, 8 mm-9 mm, or 9 mm 10 mm into the assembly 118, and/or below the assembly top surface 150.

In aspects, the at least one sensor 302 may be arranged 1 mm-10 mm from the at least one power device 200. In aspects, the at least one sensor 302 may be located 1 mm-2 mm, 2 mm-3 mm, 3 mm-4 mm, 4 mm-5 mm, 5 mm-6 mm, 6 mm-7 mm, 7 mm-8 mm, 8 mm-9 mm, or 9 mm 10 mm from the at least one power device 200.

In aspects, the at least one sensor receptacle 300 may include sensor receptacle side surfaces 306 and a sensor receptacle bottom surface 308. In aspects, the sensor receptacle side surfaces 306 may be straight, inclined, irregular, and/or the like. In aspects, the sensor receptacle bottom surface 308 may be flat, inclined, irregular shaped, and/or the like.

In aspects, the sensor receptacle side surfaces 306 may extend from the assembly top surface 150 toward the at least one power device 200. Further, the sensor receptacle side surfaces 306 may extend down to the sensor receptacle bottom surface 308. Additionally, the at least one sensor 302 may be arranged between the sensor receptacle side surfaces 306. Further, the at least one sensor 302 may be arranged on the sensor receptacle bottom surface 308.

In aspects, the sensor receptacle bottom surface 308 may be arranged 1 mm-10 mm into the assembly 118, and/or below the assembly top surface 150. In aspects, the sensor receptacle bottom surface 308 may extend 1 mm-2 mm, 2 mm-3 mm, 3 mm-4 mm, 4 mm-5 mm, 5 mm-6 mm, 6 mm-7 mm, 7 mm-8 mm, 8 mm-9 mm, or 9 mm 10 mm into the assembly 118, and/or below the assembly top surface 150.

In aspects, the at least one sensor receptacle 300 may have an opening in the assembly top surface 150 and/or the assembly 118 to allow placement of the at least one sensor 302 therein. Accordingly, the at least one sensor receptacle 300 may be a physical feature on the device package 100 and/or on the assembly top surface 150.

In other aspects, the at least one sensor receptacle 300 may be a material portion within the assembly 118. Accordingly, the at least one sensor receptacle 300 may be a physical feature within the device package 100 and/or within the assembly 118. In this aspect, the at least one sensor receptacle 300 may not have an opening in the assembly top surface 150. In this regard, the at least one sensor receptacle 300 may be a portion of material within the assembly 118 that supports and/or contains the at least one sensor 302. In this aspect, the at least one sensor receptacle 300 may be arranged as described herein between the assembly top surface 150 and the at least one power device 200. Further, in this aspect, the at least one sensor receptacle 300 may be formed by a gel, an isolation gel, a nonreflective gel, a nonreflective isolation gel, a painted gel, a painted isolation gel, a paint covered gel, a paint covered isolation gel, and/or the like. In aspects, implementation a gel, an isolation gel, a nonreflective gel, a nonreflective isolation gel, a painted gel, a painted isolation gel, a paint covered gel, a paint covered isolation gel, and/or the like may be configured to reduce infrared scattering.

In aspects, the at least one sensor 302 may be arranged in correspondence with the at least one power device 200 with a limited amount of the assembly 118 between the at least one sensor 302 and the at least one power device 200. Accordingly, the at least one sensor 302 may be configured to obtain a more accurate temperature of the at least one power device 200 and/or a more accurate junction temperature of the at least one power device 200.

In aspects, the at least one sensor 302 may be attached to the sensor receptacle bottom surface 308 by a glue, an adhesive, a potting material, a mold material, a fill material, and/or the like. Further, the at least one sensor receptacle 300 may be filled by a glue, an adhesive, a potting material, a mold material, a fill material, an isolation material, an isolation gel, and/or the like. Accordingly, the at least one sensor 302 may be embedded within the at least one sensor receptacle 300.

In particular aspects, the device package 100 may implement the at least one sensor receptacle 300 as a relatively small trench and/or trenches positioned over one or more of the at least one power device 200, while keeping only minimal amount of material of the assembly 118 between the at least one power device 200 and a bottom of the at least one sensor receptacle 300. The configuration of the at least one sensor 302 and the at least one sensor receptacle 300 may enable a very precise device junction temperature of the at least one power device 200. In aspects, the at least one sensor 302 may be implemented by different types of sensors, including infrared (IR) thermopile sensors, thermocouples, negative temperature coefficient (NTC) sensors, positive temperature coefficient (PTC) sensors, and/or the like. In addition to a single trench implementation of the at least one sensor receptacle 300, multiple trench implementations of the at least one sensor receptacle 300 can be added on the device package 100 in multiple locations to measure very accurate device junction temperatures of the at least one power device 200.

For example, the at least one sensor receptacle 300 may be implemented as a relatively small trench and/or trenches in a molding of an overmolded module configuration of the device package 100. Moreover, the at least one sensor 302 may be positioned over one or more of the internal devices, such as the at least one power device 200, while keeping only minimal amount of the assembly 118, such as a molding compound between the at least one power device 200 and the bottom of the at least one sensor receptacle 300. The disclosed implementation of the at least one sensor receptacle 300 and the at least one sensor 302 may enable a very precise device junction temperature reading of the at least one power device 200 by the at least one sensor 302. In addition to a single molding trench implementation of the at least one sensor receptacle 300, multiple trench implementations of the at least one sensor receptacle 300 can be added on the device package 100 in multiple locations to measure very accurate device junction temperatures of the at least one power device 200.

The disclosed implementations of the at least one sensor receptacle 300 may provide an externally accessible spot configured and/or designed to be in a close proximity to a device junction of the at least one power device 200. Accordingly, the disclosed implementation of the at least one sensor receptacle 300 and the at least one sensor 302 may provide a considerably more accurate and faster sensing implementation then an internal temperature sensor inside the device package 100, such as module, while allowing to manufacture of products, such as modules, without an internal temperature sensor, enabling smaller, more cost effective, and more optimized implementations of the device package 100, such as modules. The disclosed implementation of the at least one sensor receptacle 300 and the at least one sensor 302 may allow users more design flexibility on a system level, and possibly enabling safer and more noise immune temperature readings by using non-contact sensors. Further, the disclosed implementations of the at least one sensor receptacle 300 and the at least one sensor 302 may be implemented in products, such as a case module, by adding a non-reflective gel for isolation.

The disclosed implementations of the at least one sensor receptacle 300 and the at least one sensor 302 may implement a thermally optimized feature of the device package 100, such as module, which may enable optimized external temperature sensing. The disclosed implementations of the at least one sensor receptacle 300 and the at least one sensor 302 may provide a built-in and user-friendly external location feature of monitoring the internal temperature of the device externally, with sensor performance superior to internally positioned sensors.

For example, the disclosed implementations of the at least one sensor receptacle 300 and the at least one sensor 302 may be implemented by adding a “valley” feature to the device package 100, such as a power module molding surface. In this regard, an external sensor may be implemented to detect an external temperature very close to an internal device temperature of the at least one power device 200.

The disclosed implementation of the at least one sensor receptacle 300 and the at least one sensor 302 may be implemented in a molding trench and/or trenches on a surface of the assembly 118, such as a molding, down to as close to the at least one power device 200 as possible, leaving a minimum amount of the assembly 118 material, such as a molding compound. The at least one sensor receptacle 300 diameter, depth, and position may be dependent on a structure of the device package 100, for example a module structure. However, the at least one sensor receptacle 300 and the at least one sensor 302 may be applied to any overmolded device, case modules, and/or the like. For example, the disclosed implementations of the at least one sensor receptacle 300 and the at least one sensor 302 may include multiple implementations.

In particular aspects, the disclosed implementations of the at least one sensor receptacle 300 may implement a round molding trench, multiple molding trenches, a square trench, a rectangular slot, and/or the like. Additionally, the disclosed implementations of the at least one sensor receptacle 300 and the at least one sensor 302 can be added to an existing product, such as a case module, a discrete device, and/or the like.

In particular aspects, the implementations of the at least one sensor receptacle 300 may implement one or more trenches on a plastic implementation, a molding implementation, and/or the like in different types of power modules, discrete packages, and/or the like. In aspects, the disclosed implementations of the at least one sensor receptacle 300 and the at least one sensor 302 may provide precise external measurement of a device temperature of the at least one power device 200 in the device package 100, such as an overmolded module.

Implementing the at least one sensor receptacle 300 and the at least one sensor 302 may add no or minimal additional bill of material (BOM) cost as it will be part of the mold shape. Further, the disclosed implementations of the at least one sensor receptacle 300 and the at least one sensor 302 may allow more optimized, more cost effective, and smaller implementations of the device package 100, such as modules, since it will no longer need to implement an internal temperature sensor.

The disclosed implementations of the at least one sensor receptacle 300 and the at least one sensor 302 may be implemented in various products such as an overmolded platform, case modules, discrete devices, and/or the like. In aspects, the disclosed temperature sensor may be implemented in any type of device including a discrete semiconductor device, a discrete semiconductor device package, a module, a semiconductor module, a power module, a power package, a device package, a case module, an overmolded module, a semiconductor package, and/or the like.

Accordingly, the disclosed implementations of the at least one sensor receptacle 300 and the at least one sensor 302 may solve a limitation due to absence of internal temperature sensors, by adding a feature to monitor internal junction temperature externally. Moreover, the disclosed implementations of the at least one sensor receptacle 300 and the at least one sensor 302 solves limitations of current temperature sensors, by adding a feature to monitor internal junction temperature externally.

Note that the figures do not illustrate connections between the power contacts 112 and the at least one power device 200, the connections between the power contacts 112 and/or the like for ease of illustration. However, it should be recognized that the device package 100 includes connections between the power contacts 112 and the at least one power device 200, connections between the power contacts 112 and/or the like and these connections may be configured as one or more wire bonds, clips, ribbons, spring contacts, mechanical fasteners, and/or the like.

In aspects, the signal contacts 114 may be configured as one or more gate signal contacts, Kelvin-source signal contacts, sensor contacts, and/or the like. In aspects, one or more of the signal contacts 114 may be configured to be in, on, extend from, and/or the like the assembly 118. In aspects, one or more of the signal contacts 114 may be configured to be in, on, extend from, and/or the like the assembly top surface 150. In aspects, one or more of the signal contacts 114 may be configured to be in, on, extend from, and/or the like the assembly second sides 152. In aspects, one or more of the signal contacts 114 may be configured to be in, on, extend from, and/or the like the assembly first sides 151. In aspects, one or more of the signal contacts 114 may be arranged between and/or adjacent implementations of the power contacts 112. In aspects, one or more of the signal contacts 114 may be arranged opposite implementations of the power contacts 112.

In aspects, one or more of the power contacts 112 may be configured to be in, on, extend from, and/or the like the assembly 118. In aspects, one or more of the power contacts 112 may be configured to be in, on, extend from, and/or the like the assembly top surface 150. In aspects, one or more of the power contacts 112 may be configured to be in, on, extend from, and/or the like the assembly second sides 152. In aspects, one or more of the power contacts 112 may be configured to be in, on, extend from, and/or the like the assembly first sides 151.

The aspects of the device package 100 illustrated in FIGS. 1-5 may optionally be implemented in any other aspects described herein. Moreover, other aspects described herein may optionally be implemented in the device package 100 of FIGS. 1-4.

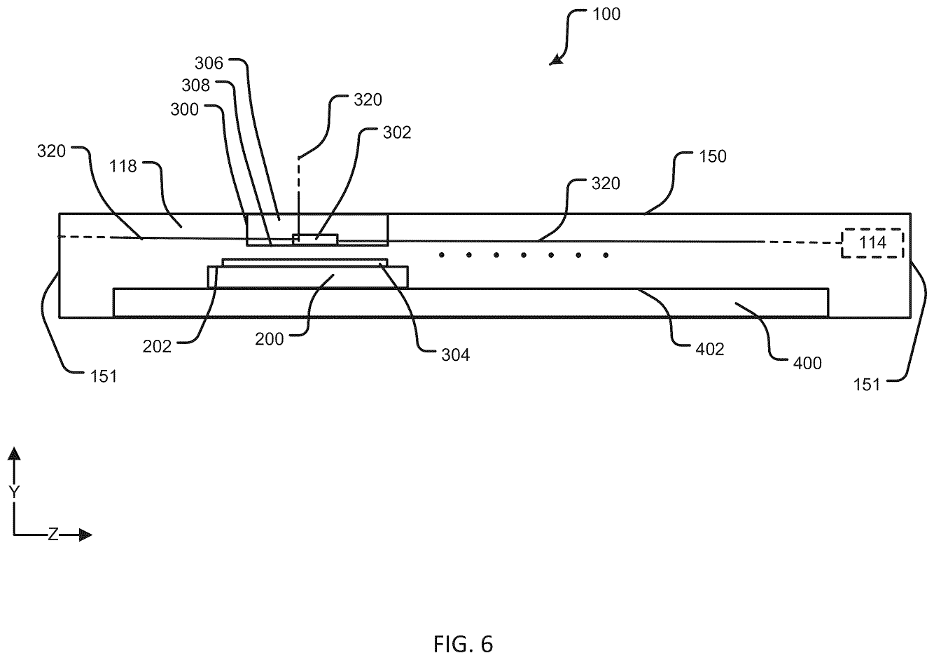

FIG. 6 illustrates a cross-sectional front view of the device package according to FIG. 1.

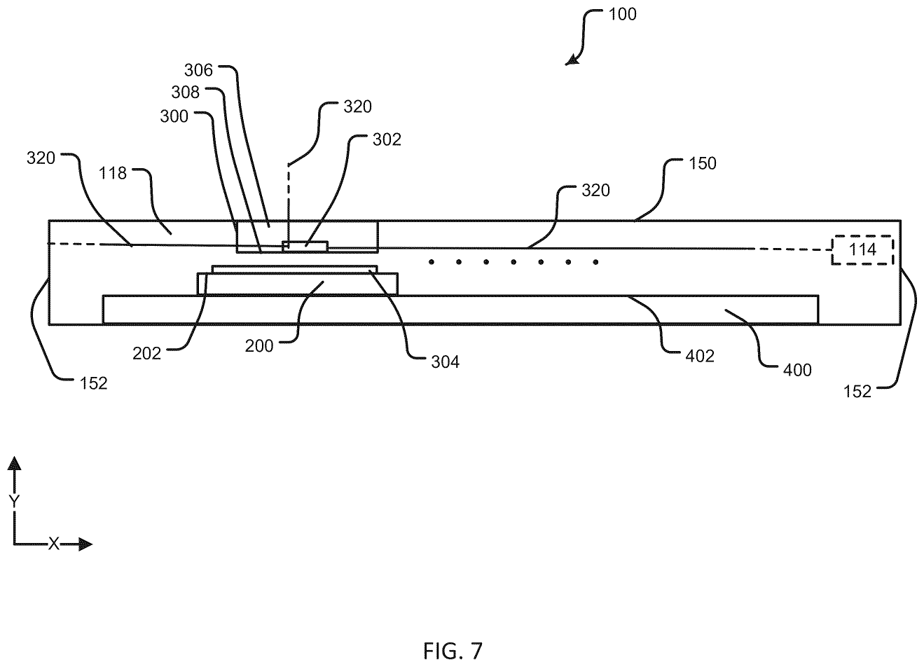

FIG. 7 illustrates a cross-sectional side view of the device package according to FIG. 1.

The aspects of the device package 100 illustrated in FIGS. 6 and 7 may optionally be implemented in any other aspects described herein. Moreover, other aspects described herein may optionally be implemented in the device package 100 of FIGS. 6 and 7.

With reference to FIG. 6 and FIG. 7, the device package 100 may include at least one power substrate 400, at least one power interconnection 304, and/or the like. In aspects of the device package 100, the at least one power device 200 may be arranged on a substrate top surface 402 of the at least one power substrate 400. In particular, the at least one power device 200 may be attached to the substrate top surface 402 of the at least one power substrate 400 by an attach, soldering, conductive epoxy, and/or the like. In other aspects, the device package 100 may be implemented without the at least one power substrate 400. In aspects, the at least one sensor 302 may not be arranged on the at least one power substrate 400. In aspects, the at least one sensor 302 may be arranged such that there is a limited distance between the at least one sensor 302 and the at least one power device 200 and/or the at least one power interconnection 304.

In aspects, the at least one power substrate 400 may include a die attach region where the at least one power device 200 is arranged on the substrate top surface 402 of the at least one power substrate 400. In aspects, the at least one sensor receptacle 300 and/or the at least one sensor 302 may be arranged above the die attach region of the at least one power device 200.

In aspects, the at least one power interconnection 304 may be connected to the at least one power device 200 and may further be electrically connected to one or more of the power contacts 112. In aspects, the at least one power interconnection 304 may be configured as one or more lead frames, wire bonds, clips, ribbons, and/or the like. In particular, the at least one power interconnection 304 may be attached to a power device top surface 202 of the at least one power device 200 by soldering, conductive epoxy, and/or the like.

As further illustrated in FIG. 6 and FIG. 7, the at least one sensor 302 may be arranged above the at least one power device 200 and/or above a portion of the at least one power interconnection 304 attached to the at least one power device 200. In particular, the at least one sensor 302 may be arranged in or on the sensor receptacle bottom surface 308 between the sensor receptacle side surfaces 306 above the at least one power device 200 and/or above a portion of the at least one power interconnection 304 attached to the at least one power device 200.

Additionally, FIG. 6 and FIG. 7 illustrates sensor interconnects 320. The sensor interconnects 320 may connect to the at least one sensor 302 and receive temperature signals from the at least one sensor 302. Further, if needed, the sensor interconnects 320 may provide power to the at least one sensor 302.

In aspects, the sensor interconnects 320 may extend outside of the assembly 118 for external connection to a temperature measurement system. In aspects, the temperature measurement system may be calibrated for any temperature offset of the at least one sensor 302. In particular, the temperature measurement system may be calibrated for any temperature offset of the at least one sensor 302 caused by a construction and location of the at least one sensor receptacle 300 and/or the at least one sensor 302 within the device package 100. In aspects, the temperature measurement system may be self calibrated for any temperature offset of the at least one sensor 302. In aspects, the sensor interconnects 320 may extend to the assembly first sides 151, extend out of the at least one sensor receptacle 300, extend to an implementation of the signal contacts 114, extend to the assembly second sides 152, and/or the like.

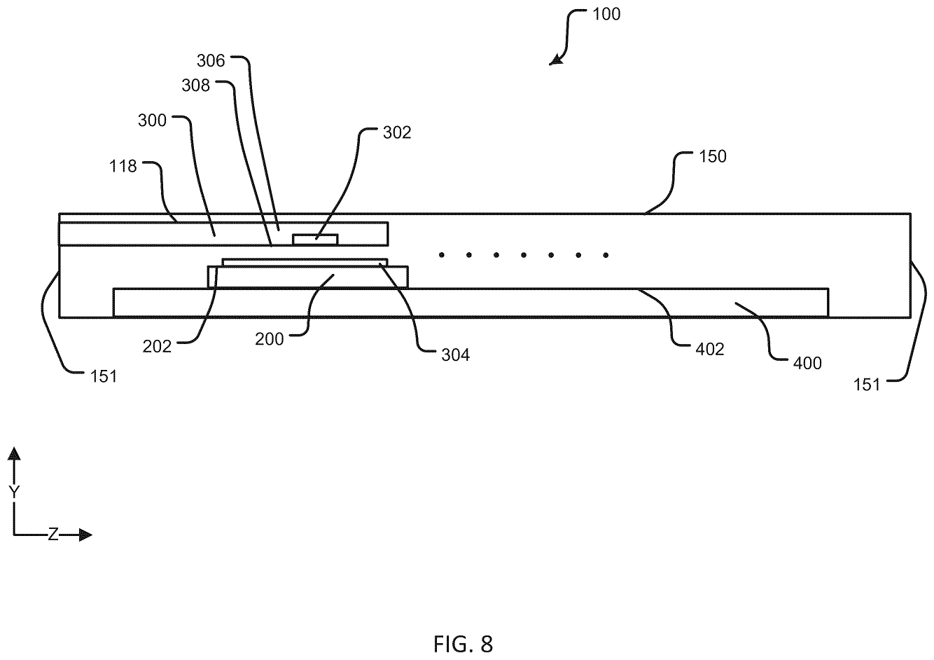

FIG. 8 illustrates a cross-sectional front view of the device package according to aspects of the disclosure.

The aspects of the device package 100 illustrated in FIG. 8 may optionally be implemented in any other aspects described herein. Moreover, other aspects described herein may optionally be implemented in the device package 100 of FIG. 8.

In particular, FIG. 8 illustrates that the at least one sensor receptacle 300 may be arranged to extend to at least one of the assembly first sides 151. In aspects, the at least one sensor receptacle 300 may have an open end on at least one of the assembly first sides 151. As further illustrated in FIG. 8, the at least one sensor 302 may be arranged above the at least one power device 200 and/or above a portion of the at least one power interconnection 304 attached to the at least one power device 200. In particular, the at least one sensor 302 may be arranged in or on the sensor receptacle bottom surface 308 between the sensor receptacle side surfaces 306 above the at least one power device 200 and/or above a portion of the at least one power interconnection 304 attached to the at least one power device 200.

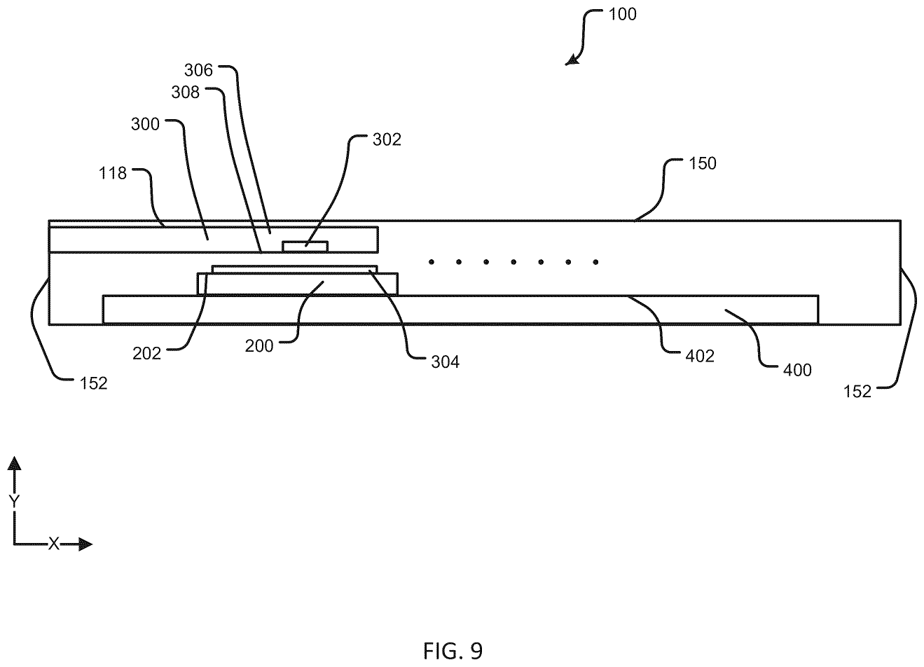

FIG. 9 illustrates a cross-sectional front view of the device package according to aspects of the disclosure.

The aspects of the device package 100 illustrated in FIG. 9 may optionally be implemented in any other aspects described herein. Moreover, other aspects described herein may optionally be implemented in the device package 100 of FIG. 9.

In particular, FIG. 9 illustrates that the at least one sensor receptacle 300 may be arranged to extend to at least one of the assembly second sides 152. In aspects, the at least one sensor receptacle 300 may have an open end on at least one of the assembly second sides 152. As further illustrated in FIG. 9, the at least one sensor 302 may be arranged above the at least one power device 200 and/or above a portion of the at least one power interconnection 304 attached to the at least one power device 200. In particular, the at least one sensor 302 may be arranged in or on the sensor receptacle bottom surface 308 between the sensor receptacle side surfaces 306 above the at least one power device 200 and/or above a portion of the at least one power interconnection 304 attached to the at least one power device 200.

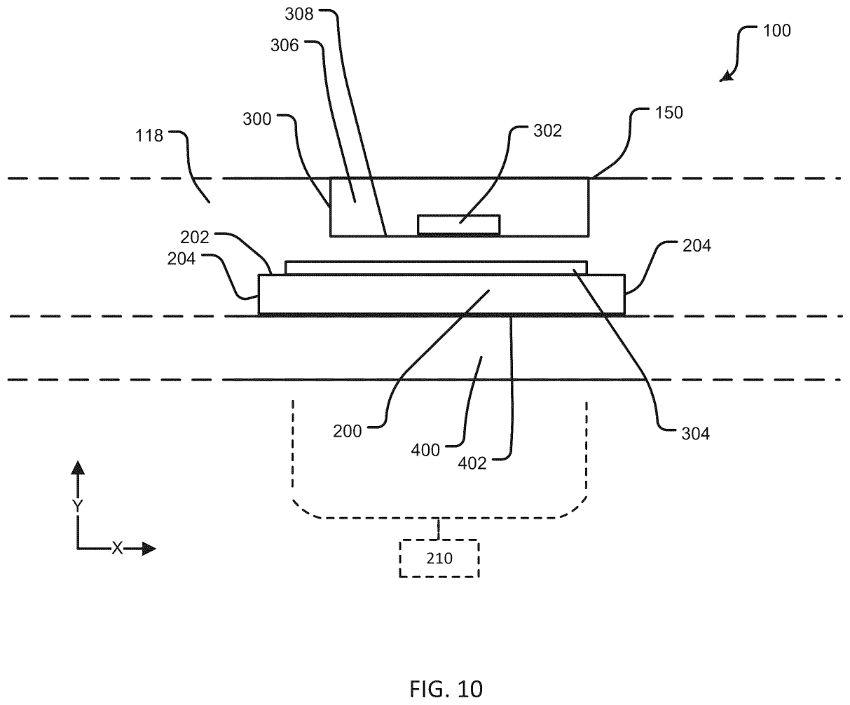

FIG. 10 illustrates a further cross-sectional front view of the device package according to FIG. 1.

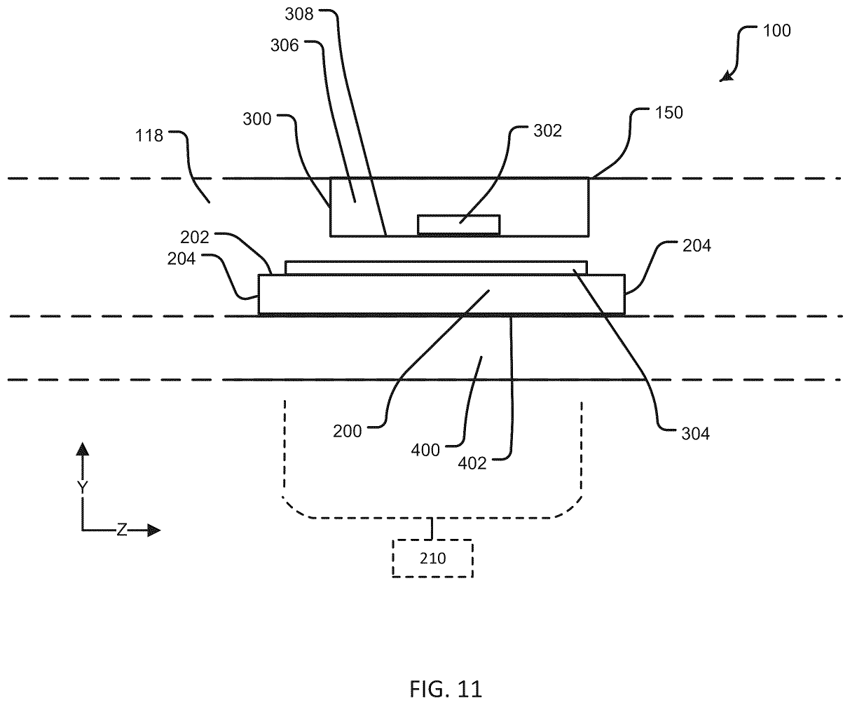

FIG. 11 illustrates a further cross-sectional side view of the device package according to FIG. 1.

The aspects of the device package 100 illustrated in FIGS. 10 and 11 may optionally be implemented in any other aspects described herein. Moreover, other aspects described herein may optionally be implemented in the device package 100 of FIGS. 10 and 11.

With reference to FIG. 10 and FIG. 11, the at least one power device 200 may include power device sides 204 that extend away from the power device top surface 202 and/or the at least one power interconnection 304. In aspects, the at least one sensor 302 may be arranged between the power device sides 204 of the at least one power device 200.

More specifically, the at least one sensor 302 may be arranged on an axis perpendicular to the power device top surface 202 and the axis may extend through the at least one power device 200. Further, the at least one sensor 302 may be arranged on an axis perpendicular to the power device top surface 202 and the at least one sensor 302 may be further arranged between axes that extend through the power device sides 204.

As further shown in FIG. 10, the at least one power device 200 may include a power device active area 210, which may relate to an area of detection of a junction temperature of the at least one power device 200. In aspects, the device package 100 may be configured to arrange the at least one sensor 302 in a middle section or middle of the at least one power device 200 and/or the power device active area 210.

In aspects, the at least one sensor 302 may be arranged vertically above the power device active area 210. In aspects, the at least one sensor 302 may be arranged along an axis perpendicular to the power device top surface 202 and/or the substrate top surface 402 within the power device active area 210.

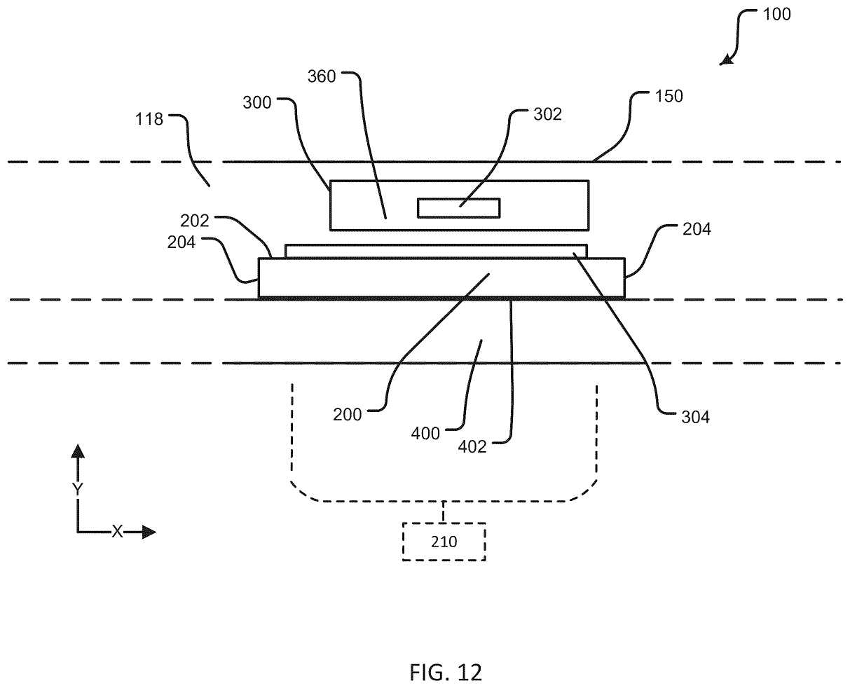

FIG. 12 illustrates a further cross-sectional front view of the device package according to FIG. 1.

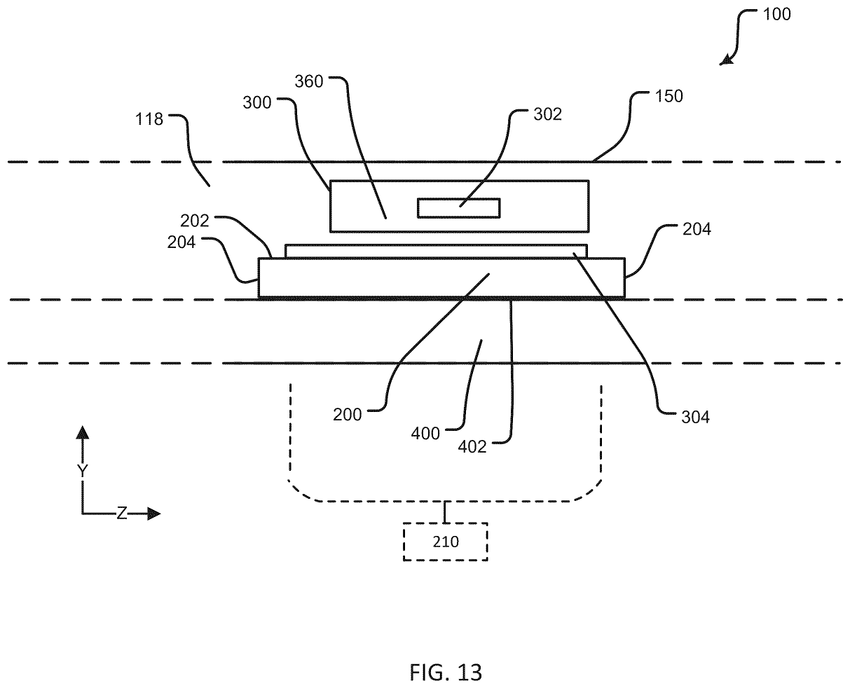

FIG. 13 illustrates a further cross-sectional side view of the device package according to FIG. 1.

The aspects of the device package 100 illustrated in FIGS. 12 and 13 may optionally be implemented in any other aspects described herein. Moreover, other aspects described herein may optionally be implemented in the device package 100 of FIGS. 12 and 13.

In aspects, the at least one sensor receptacle 300 may be a sensor holding material portion 360 within the assembly 118. Accordingly, the at least one sensor receptacle 300 may be a physical feature within the device package 100 and/or within the assembly 118. In this aspect, the at least one sensor receptacle 300 may not have an opening in the assembly top surface 150.

In this regard, the at least one sensor receptacle 300 may be the sensor holding material portion 360 within the assembly 118 that supports and/or contains the at least one sensor 302. In this aspect, the at least one sensor receptacle 300 may be configured as the sensor holding material portion 360 arranged as described herein between the assembly top surface 150 and the at least one power device 200. In aspects, the sensor holding material portion 360 may be arranged only in locations between the at least one sensor 302 and the at least one power device 200. In other aspects, the sensor holding material portion 360 may partially fill an open area between the assembly top surface 150 and the at least one power device 200. In other aspects, the sensor holding material portion 360 may substantially fill an open area between the assembly top surface 150 and the at least one power device 200. In other aspects, the sensor holding material portion 360 may completely fill an open area between the assembly top surface 150 and the at least one power device 200.

Further, in this aspect, the at least one sensor receptacle 300 and/or the sensor holding material portion 360 may be formed by a gel, an isolation gel, a nonreflective gel, a nonreflective isolation gel, a painted gel, a painted isolation gel, a paint covered gel, a paint covered isolation gel, and/or the like. Accordingly, the at least one sensor 302 may be arranged in the at least one sensor receptacle 300 and/or the sensor holding material portion 360 between the assembly top surface 150 and the at least one power device 200. In aspects, the sensor holding material portion 360 may be configured to reduce infrared scattering. In aspects, implementation of a gel, an isolation gel, a nonreflective gel, a nonreflective isolation gel, a painted gel, a painted isolation gel, a paint covered gel, a paint covered isolation gel, and/or the like may be configured to reduce infrared scattering.

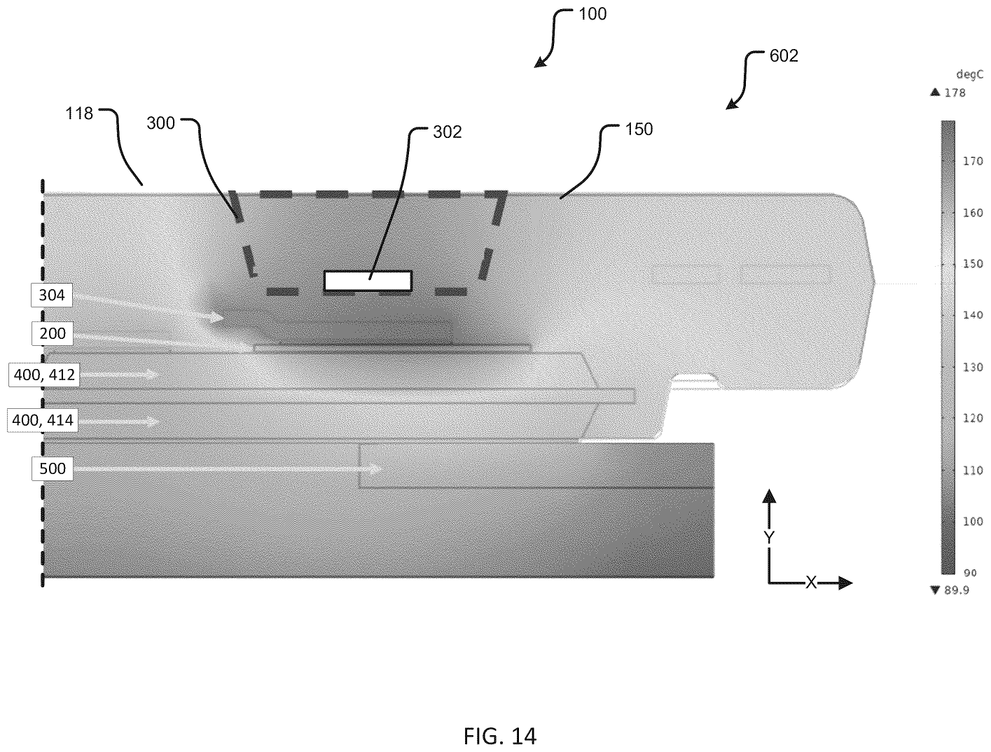

FIG. 14 illustrates a thermal diagram of the device package implementing the at least one sensor receptacle and the at least one temperature sensor according to aspects of the disclosure.

In particular, FIG. 14 illustrates a thermal diagram 602 of the device package 100 implementing the at least one sensor receptacle 300 and the at least one sensor 302 according to aspects of the disclosure. In this regard, the thermal diagram 602 illustrates a location and a temperature within the device package 100 including a location and temperature within the at least one power device 200, the at least one power interconnection 304, the assembly 118, the at least one sensor receptacle 300, the at least one sensor 302, and/or the like.

As is apparent from the thermal diagram 602 of the device package 100 illustrated in FIG. 14, the location of the at least one sensor 302 provides a much more accurate detection of the temperature of the at least one power device 200, a junction temperature of the at least one power device 200, and/or a temperature of the at least one power interconnection 304. In this regard, a location of the at least one sensor 302 positioned elsewhere within the device package 100 and/or the assembly 118, such as along the X axis on the at least one power substrate 400 would not accurately determine a temperature of the at least one power device 200, a junction temperature the at least one power device 200, and/or a temperature the at least one power interconnection 304. Likewise, it should be appreciated that the at least one sensor 302 measuring another property within the at least one power device 200 may likewise provide a much more accurate detection of that property of the at least one power device 200.

In the implementation of the device package 100 illustrated in FIG. 14, the at least one power substrate 400 has been implemented with an upper substrate 412 and a lower substrate 414. Additionally, the implementation of the device package 100 illustrated in FIG. 14 has been implemented with a cold plate 500.

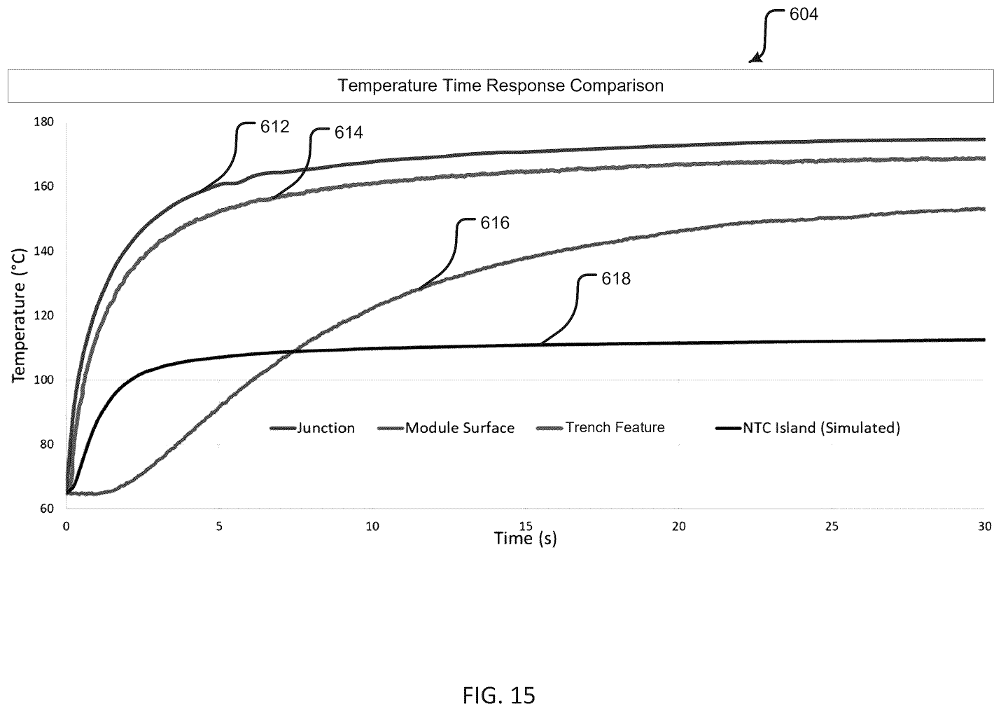

FIG. 15 illustrates a temperature time response comparison graph of different temperature sensor implementations in an exemplary implementation of the device package.

In particular, FIG. 15 illustrates a temperature time response comparison graph 604 of different temperature sensor locations in an exemplary implementation of the device package 100. More specifically, the temperature time response comparison graph 604 illustrates a temperature in Celsius along a vertical axis along a left side; and the temperature time response comparison graph 604 illustrates a time in seconds along a horizontal axes.

Further, the temperature time response comparison graph 604 provides a junction temperature line 612 that represents an actual junction temperature of the at least one power device 200 of a module implementation of the device package 100. In particular, the junction temperature line 612 is annotated as “Junction” in the temperature time response comparison graph 604.

Additionally, the temperature time response comparison graph 604 provides a module surface temperature line 616 that represents a temperature of a module surface of the module implementation of the device package 100. In particular, the module surface temperature line 616 is annotated as “Module Surface” in the temperature time response comparison graph 604.

Further, the temperature time response comparison graph 604 provides an implementation temperature line 614 that represents a temperature as determined by an implementation of the at least one sensor 302 and the at least one sensor receptacle 300 of the disclosure in the module implementation of the device package 100. In particular, the implementation temperature line 614 is annotated as “Trench Feature” in the temperature time response comparison graph 604.

Finally, the temperature time response comparison graph 604 provides a substrate temperature line 618 that represents a simulated temperature of an implementation of the at least one temperature sensor arranged on an island of the at least one power substrate 400 in the module implementation of the device package 100. In particular, the substrate temperature line 618 is annotated as “NTC Island (Simulated)” in the temperature time response comparison graph 604.

As can be clearly seen by the temperature time response comparison graph 604, the implementation temperature line 614 provides nearly the same temperature detection as the junction temperature line 612. Further, the implementation temperature line 614 provides nearly the same rate of temperature change detection as the junction temperature line 612. Additionally, the implementation temperature line 614 provides minimal delay in detecting a temperature change in comparison to the junction temperature line 612.

On the other hand, as can be clearly seen by the temperature time response comparison graph 604, the module surface temperature line 616 and the substrate temperature line 618 do not provide the same temperature detection as the junction temperature line 612. In particular, temperatures provided by the module surface temperature line 616 and the substrate temperature line 618 are much less accurate.

Further, as can be clearly seen by the temperature time response comparison graph 604, the module surface temperature line 616 and the substrate temperature line 618 do not provide the same rate of temperature change detection as the junction temperature line 612. In particular, rate of temperature changes provided by the module surface temperature line 616 and the substrate temperature line 618 are much less accurate.

Moreover, as can be clearly seen by the temperature time response comparison graph 604, the module surface temperature line 616 and the substrate temperature line 618 exhibit substantial delay in detecting a temperature change in comparison to the junction temperature line 612. In particular, there is a great deal of delay in temperature changes provided by the module surface temperature line 616 and the substrate temperature line 618 in comparison to the junction temperature line 612.

Accordingly, implementation of the at least one sensor receptacle 300 and the at least one sensor 302 of the disclosure provides greater temperature detection accuracy. Moreover, implementation of the at least one sensor receptacle 300 and the at least one sensor 302 of the disclosure provides more accurate determination of rate of temperature changes in the at least one power device 200 of the device package 100. Further, implementation of the at least one sensor receptacle 300 and the at least one sensor 302 of the disclosure provides faster determination of temperature changes and/or reduced delay in determination of temperature changes in the at least one power device 200 of the device package 100. In this regard, implementation of the at least one sensor receptacle 300 and the at least one sensor 302 of the disclosure provides fast transient changes in temperature in the at least one power device 200 of the device package 100. Likewise, it should be appreciated that the at least one sensor 302 measuring another property within the at least one power device 200 may likewise provide a much more accurate and faster detection of that property of the at least one power device 200.

In aspects, the signal contacts 114 may be implemented using any type of connector technology and/or configuration including one or more of pin connector configurations, pad configurations, press-fit connection blade connector configurations, plug configurations, plug-and-socket connection configurations, plug configurations, socket configurations, male connection configurations, pin contact configurations, female socket configurations, pogo pin configurations, spring loaded connector configurations, locking connector configurations, keying connector configurations, and/or the like.

In aspects, the device package 100 may be configured such that there may be any number of the signal contacts 114 including two of the signal contacts 114, three of the signal contacts 114, four of the signal contacts 114 or more. Additional implementations of the signal contacts 114 may be implemented.

In particular aspects of the device package 100, the signal contacts 114 may be communicate signals for sensing a property of the at least one power device 200. In particular aspects of the device package 100, the signal contacts 114 may be communicate signals for current sensing. The current sensing may be implemented using a current sensor implemented by the device package 100. In particular aspects of the device package 100, the signal contacts 114 may be communicate signals for voltage sensing. The voltage sensing may be implemented using a voltage sensor implemented by the device package 100. In particular aspects of the device package 100, the signal contacts 114 may be communicate signals for humidity sensing. The humidity sensing may be implemented using a humidity sensor implemented by the device package 100.

The at least one power device 200 may be implemented as a power semiconductor device, a transistor device, a power transistor device, a diode, a power diode, a metal-oxide-semiconductor field-effect transistor (MOSFET) device, an insulated-gate bipolar transistor (IGBT) device, and/or the like. In aspects, the at least one power device 200 may be implemented as any type of device implementing a Silicon device, silicon carbide (SiC) device, gallium nitride (GaN) device, and/or the like. In aspects, the at least one power device 200 may be implemented as a power semiconductor device, a transistor device, a power transistor device, a diode, a power diode, a metal-oxide-semiconductor field-effect transistor (MOSFET) device, an insulated-gate bipolar transistor (IGBT) device that are implemented with Silicon device, silicon carbide (SiC) device, gallium nitride (GaN) device, and/or the like.

The device package 100 may include multiple devices in parallel and arranged into multiple switch positions. Aspects of the device package 100 may serve many functions including: electrical interconnection, electrical isolation, heat transfer, mechanical structure, protection of the devices from environmental contamination and moisture, external electrical and thermal connection interfaces, compliance with safety standards such as voltage creepage and clearance distances, and/or the like.

In aspects, the power contacts 112 may be structured and arranged to have at least in part a flat portion in a plane of the y-axis, the x-axis, and/or the z-axis. The flat portion of the power contacts 112 may form a contact to other components, external components, and/or the like.

In aspects, the power contacts 112 may be configured to be electrically and mechanically connect to another implementation of the device package 100, a bus bar, and/or the like. In aspects, the power contacts 112 of the device package 100 may be configured to be electrically and mechanically connected to another component, such as a system, an application component, an application device, a wire, a clipped connection, and/or the like. The electrical and mechanical connections between the power contacts 112 and the another component may be implemented through a number of structures, methods, and/or the like. In aspects, the electrical and mechanical connections between the power contacts 112 and the another component may include welded portions, welding, soldered portions, soldering, conductive epoxy, clips, spring contacts, mechanical fasteners, and/or the like. The welded portions may include laser welded portions, ultrasonic welding portions, and/or the like. The welding may include laser welding, ultrasonic welding, and/or the like.

In aspects, the signal contacts 114 of the device package 100 may be configured to be electrically and mechanically connected to another component, such as a gate driver, a gate driver printed circuit board (PCB), a wire, a clipped connection, and/or the like. The electrical and mechanical connections between the signal contacts 114 and the another component may be implemented through a number of structures, methods, and/or the like. In aspects, the electrical and mechanical connections between the signal contacts 114 and the another component may include welded portions, welding, soldered portions, soldering, conductive epoxy, clips, spring contacts, mechanical fasteners, and/or the like. The welded portions may include laser welded portions, ultrasonic welding portions, and/or the like. The welding may include laser welding, ultrasonic welding, and/or the like.

In aspects, the device package 100 may be configured on a backside thereof with a thermal pad. The thermal pad may be configured as an exposed metal thermal pad. Further, the thermal pad may be configured with a large surface to thermally and mechanically attach to another component. The surface of the thermal pad may be configured to facilitate the removal of waste heat from conduction, switching, package resistive losses, and/or the like from the device package 100.

Additionally, the thermal pad may be configured to be attached via a connection to another component. The connection of the thermal pad to another component may be implemented by sintering, soldering, conductive epoxy, thermal paste, and/or the like. In this regard, the thermal pad may be configured to form the connection to another component utilizing one or more of these processes.

In aspects, the assembly 118 of the device package 100 may be a case, a molded case, a plastic case, an overmolded case, an injection molded case, a housing, a molded housing, a plastic housing, an overmolded housing, an injection molded housing, and/or the like. In aspects, the assembly 118 of the device package 100 may include various materials including a plastic material, a synthetic material, a dielectric material, a mold compound, a dielectric mold compound, and/or the like. The assembly 118 may surround one or more components of the device package 100, a majority the components of the device package 100, all of the components of the device package 100 with the exception of portions of the power contacts 112, the signal contacts 114, the thermal pad, and/or the like. The assembly 118 may be configured, structured, and/or arranged with the device package 100 to provide electrical isolation, voltage safety distances, mechanical support to the internal layout and power semiconductor devices, and/or the like.

In aspects, the device package 100 may be configured with circuit topologies implementing one or more implementations of the device package 100. In this regard, arrangements of one or more implementations of the device package 100 may be configured as single positions and bridge legs, by themselves or with many in parallel, can achieve any of the circuit topologies described herein at any number of various scalable output power levels.

For example, parallel implementations of the device package 100 along the z-axis. In aspects, the parallel implementations of the device package 100 may be electrically connected at corresponding implementations of the power contacts 112 (not shown). Further, there may be any number of parallel implementations of the device package 100 along the x-axis.

In aspects of the disclosure, the device package 100 may be configured as a type of package that may be referred to as an ‘overmolded power module.’ In aspects, during manufacture multiple implementations of the device package 100 may be assembled on a patterned lead frame array, encapsulated with a mold compound or similar composite dielectric material, singulated from the lead frame array, and finally the electrical contacts are formed into shape. Often, multiple parts of the device package 100 may be fabricated on a single lead frame to maximize throughput. The processes of manufacturing the device package 100 and the various configurations of the device package 100 described herein may be highly compatible with serial processing in an automated manufacturing line.

In aspects, the at least one power device 200 implemented by the device package 100 may be configured as power devices that may be configured and/or implemented as power semiconductor switches. In aspects, the power semiconductor switches implemented by the device package 100 may be sized to minimize a device area for a given power requirement.

In aspects, the device package 100 may implement one or more device attaches. In aspects, the one or more device attaches may comprise a material for attaching the at least one power device 200 to the at least one power substrate 400. The material of the one or more device attaches may be selected and/or implemented to (1) maximize thermal performance, (2) minimize cost, and/or the like.

In aspects, the at least one power substrate 400 implemented by the device package 100 may comprise a material. The material of the at least one power substrate 400 may be selected and/or implemented to (1) maximize thermal performance, (2) maximize reliability, (3) minimize cost, and/or the like.

Moreover, the device package 100 may be implemented in numerous circuit topologies including a single switch configuration, half bridge configuration, full bridge configuration, three phase bridge configuration (also called a six pack), buck configuration, boost configuration, buck-boost configuration, ćuk configuration, a common source configuration, a common drain configuration, a neutral point clamp configuration, and/or the like. Applications of the device package 100 may include a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, and electric vehicles (EVs), a converter, motor drives, solar inverters, circuit breakers, protection circuits, DC-DC converters, and/or the like.

Accordingly, the disclosure has set forth a device package that provides a more accurate and/or a more direct measurement of a semiconductor device property. Moreover, the disclosure has set forth a process of implementing a device package to provide a more accurate and/or a more direct measurement of a semiconductor device property.

The following are a number of nonlimiting EXAMPLES of aspects of the disclosure.

One EXAMPLE: a device package includes an assembly and the assembly comprises an assembly top surface. The device package in addition includes signal contacts arranged in and/or on the assembly. The package moreover includes power contacts arranged in and/or on the assembly. The package also includes at least one power device. The package further includes at least one sensor receptacle. The package in addition includes at least one sensor arranged in the at least one sensor receptacle. The package moreover includes where the at least one sensor receptacle is arranged in and/or on the assembly top surface.

The above-noted EXAMPLE may further include any one or a combination of more than one of the following EXAMPLES: The device package of the above-noted EXAMPLE where the at least one sensor is arranged on an axis perpendicular to a top surface of the at least one power device. The device package of the above-noted EXAMPLE where the at least one sensor receptacle and the at least one sensor are arranged above the at least one power device. The device package of the above-noted EXAMPLE where the at least one power device comprises power device sides that extend away from a top surface of the at least one power device; and where the at least one sensor is arranged between the power device sides of the at least one power device. The device package of the above-noted EXAMPLE where the at least one power device comprises a power device active area that relates to an area of detection of a junction temperature of the at least one power device; and where the at least one sensor is arranged in a middle section or middle of the power device active area. The device package of the above-noted EXAMPLE where the at least one sensor is configured to measure a temperature of the at least one power device, measure a temperature of a device junction of the at least one power device, and/or measure a junction temperature of the at least one power device. The device package of the above-noted EXAMPLE where the at least one sensor comprises a contactless sensor. The device package of the above-noted EXAMPLE where the at least one sensor is configured to measure a temperature of the at least one power device, measure a temperature of a device junction of the at least one power device, and/or measure a junction temperature of the at least one power device without contacting the at least one power device. The device package of the above-noted EXAMPLE where the at least one sensor is arranged above a middle section or middle area of the at least one power device. The device package of the above-noted EXAMPLE where the at least one sensor is arranged above the at least one power device along a vertical axis. The device package of the above-noted EXAMPLE where the at least one sensor is arranged above the at least one power device with a portion of the assembly therebetween. The device package of the above-noted EXAMPLE where the at least one sensor receptacle comprises a trench, a valley, a cavity, a channel, a groove, a pocket, an aperture, a hole, a location, a holder, a divot, a tunnel, and/or an arrangement. The device package of the above-noted EXAMPLE where the at least one power device comprises a plurality of the at least one power device. The device package of the above-noted EXAMPLE where the at least one sensor receptacle comprises a plurality of the at least one sensor receptacle; and where the at least one sensor comprises a plurality of the at least one sensor. The device package of the above-noted EXAMPLE where the at least one sensor receptacle comprises a circular shaped configuration, a square shape configuration, a rectangular shape configuration, a polygonal shape configuration, and/or an irregular shape configuration. The device package of the above-noted EXAMPLE where the at least one sensor receptacle is configured, arranged, and/or formed, during formation of the assembly. The device package of the above-noted EXAMPLE where the at least one sensor receptacle comprises a molded structure and/or a molded sensor receptacle. The device package of the above-noted EXAMPLE where the at least one sensor receptacle is configured, arranged, and/or formed, after formation of the assembly. The device package of the above-noted EXAMPLE where the at least one sensor receptacle comprises a machined structure and/or a machined sensor receptacle. The device package of the above-noted EXAMPLE where the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor. The device package of the above-noted EXAMPLE where the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor. The device package of the above-noted EXAMPLE where the at least one sensor is arranged on an external surface of the assembly. The device package of the above-noted EXAMPLE where the at least one sensor is not arranged on a component within the assembly. The device package of the above-noted EXAMPLE where the at least one sensor is self-calibrated. The device package of the above-noted EXAMPLE where the at least one sensor receptacle comprises sensor receptacle side surfaces and a sensor receptacle bottom surface; where the sensor receptacle side surfaces extend from the assembly top surface toward the at least one power device; and where at least one sensor is arranged on the sensor receptacle bottom surface. The device package of the above-noted EXAMPLE where the sensor receptacle bottom surface is arranged 1 mm 10 mm into the assembly, and/or below the assembly top surface. The device package of the above-noted EXAMPLE where the at least one sensor is attached to the sensor receptacle bottom surface by a glue, an adhesive, a potting material, a mold material, and/or a fill material. The device package of the above-noted EXAMPLE where the at least one sensor receptacle comprises an opening in the assembly top surface configured to allow insertion of the at least one sensor therein. The device package of the above-noted EXAMPLE where the signal contacts comprise one or more of a gate signal contact, a Kelvin-source signal contact, and/or a sensor contact. The device package of the above-noted EXAMPLE includes at least one power substrate, where the at least one power device is arranged on a top surface of the at least one power substrate, where the at least one sensor receptacle and/or the at least one sensor are arranged above the at least one power device and the at least one power substrate. The device package of the above-noted EXAMPLE includes at least one power substrate, where the at least one power substrate comprises a die attach region where the at least one power device is arranged on a top surface of the at least one power substrate; and where the at least one sensor receptacle and/or the at least one sensor are arranged above the die attach region and the at least one power device. The device package of the above-noted EXAMPLE includes sensor interconnects configured to connect to the at least one sensor and receive temperature signals from the at least one sensor. The device package of the above-noted EXAMPLE where the sensor interconnects extend outside of the assembly for external connection to a temperature measurement system. The device package of the above-noted EXAMPLE where the sensor interconnects extend to one of the signal contacts. The device package of the above-noted EXAMPLE where the at least one sensor receptacle comprises a sensor holding material portion within the assembly; and where the sensor holding material portion supports and/or contains the at least one sensor. The device package of the above-noted EXAMPLE where the sensor holding material portion comprises a gel, an isolation gel, a nonreflective gel, a nonreflective isolation gel, a painted gel, a painted isolation gel, a paint covered gel, and/or a paint covered isolation gel. The device package of the above-noted EXAMPLE where the assembly comprises a housing, a case, a molded housing, a molded case, an overmolded housing, and/or an overmolded case. The device package of the above-noted EXAMPLE comprising a power package, a semiconductor package, a power semiconductor package, a module, a power module, a power semiconductor module, an overmolded module, an overmolded power module, a case module, a discrete device, and/or a discrete power device. The device package of the above-noted EXAMPLE where the at least one power device comprises a power semiconductor device, a transistor device, a power transistor device, a diode, a power diode, a metal-oxide-semiconductor field-effect transistor (MOSFET) device, and/or an insulated-gate bipolar transistor (IGBT) device. The device package of the above-noted EXAMPLE where the at least one power device comprises a Silicon device, silicon carbide (SiC) device, and/or gallium nitride (GaN) device.

One EXAMPLE: a device package includes an assembly and the assembly comprises an assembly top surface. The device package in addition includes signal contacts arranged in and/or on the assembly. The package moreover includes power contacts arranged in and/or on the assembly. The package also includes at least one power device. The package further includes at least one sensor receptacle. The package in addition includes at least one sensor arranged in the at least one sensor receptacle. The package moreover includes where the at least one sensor is arranged on an axis perpendicular to a top surface of the at least one power device.

The above-noted EXAMPLE may further include any one or a combination of more than one of the following EXAMPLES: The device package of the above-noted EXAMPLE where the at least one sensor receptacle is arranged in and/or on the assembly top surface. The device package of the above-noted EXAMPLE where the at least one power device comprises power device sides that extend away from a top surface of the at least one power device; and where the at least one sensor is arranged between the power device sides of the at least one power device. The device package of the above-noted EXAMPLE where the at least one power device comprises a power device active area that relates to an area of detection of a junction temperature of the at least one power device; and where the at least one sensor is arranged in a middle section or middle of the power device active area. The device package of the above-noted EXAMPLE where the at least one sensor is configured to measure a temperature of the at least one power device, measure a temperature of a device junction of the at least one power device, and/or measure a junction temperature of the at least one power device. The device package of the above-noted EXAMPLE where the at least one sensor comprises a contactless sensor. The device package of the above-noted EXAMPLE where the at least one sensor is configured to measure a temperature of the at least one power device, measure a temperature of a device junction of the at least one power device, and/or measure a junction temperature of the at least one power device without contacting the at least one power device. The device package of the above-noted EXAMPLE where the at least one sensor is arranged above a middle section or middle area of the at least one power device. The device package of the above-noted EXAMPLE where the at least one sensor is arranged above the at least one power device along a vertical axis. The device package of the above-noted EXAMPLE where the at least one sensor is arranged above the at least one power device with a portion of the assembly therebetween. The device package of the above-noted EXAMPLE where the at least one sensor receptacle comprises a trench, a valley, a cavity, a channel, a groove, a pocket, an aperture, a hole, a location, a holder, a divot, a tunnel, and/or an arrangement. The device package of the above-noted EXAMPLE where the at least one power device comprises a plurality of the at least one power device. The device package of the above-noted EXAMPLE where the at least one sensor receptacle comprises a plurality of the at least one sensor receptacle; and where the at least one sensor comprises a plurality of the at least one sensor. The device package of the above-noted EXAMPLE where the at least one sensor receptacle comprises a circular shaped configuration, a square shape configuration, a rectangular shape configuration, a polygonal shape configuration, and/or an irregular shape configuration. The device package of the above-noted EXAMPLE where the at least one sensor receptacle is configured, arranged, and/or formed, during formation of the assembly. The device package of the above-noted EXAMPLE where the at least one sensor receptacle comprises a molded structure and/or a molded sensor receptacle. The device package of the above-noted EXAMPLE where the at least one sensor receptacle is configured, arranged, and/or formed, after formation of the assembly. The device package of the above-noted EXAMPLE where the at least one sensor receptacle comprises a machined structure and/or a machined sensor receptacle. The device package of the above-noted EXAMPLE where the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor. The device package of the above-noted EXAMPLE where the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor. The device package of the above-noted EXAMPLE where the at least one sensor is arranged on an external surface of the assembly. The device package of the above-noted EXAMPLE where the at least one sensor is not arranged on a component within the assembly. The device package of the above-noted EXAMPLE where the at least one sensor is self-calibrated. The device package of the above-noted EXAMPLE where the at least one sensor receptacle comprises sensor receptacle side surfaces and a sensor receptacle bottom surface; where the sensor receptacle side surfaces extend from the assembly top surface toward the at least one power device; and where at least one sensor is arranged on the sensor receptacle bottom surface. The device package of the above-noted EXAMPLE where the sensor receptacle bottom surface is arranged 1 mm 10 mm into the assembly, and/or below the assembly top surface. The device package of the above-noted EXAMPLE where the at least one sensor is attached to the sensor receptacle bottom surface by a glue, an adhesive, a potting material, a mold material, and/or a fill material. The device package of the above-noted EXAMPLE where the at least one sensor receptacle comprises an opening in the assembly top surface configured to allow insertion of the at least one sensor therein. The device package of the above-noted EXAMPLE where the signal contacts comprise one or more of a gate signal contact, a Kelvin-source signal contact, and/or a sensor contact. The device package of the above-noted EXAMPLE includes at least one power substrate, where the at least one power device is arranged on a top surface of the at least one power substrate, where the at least one sensor receptacle and/or the at least one sensor are arranged above the at least one power device and the at least one power substrate. The device package of the above-noted EXAMPLE includes at least one power substrate, where the at least one power substrate comprises a die attach region where the at least one power device is arranged on a top surface of the at least one power substrate; and where the at least one sensor receptacle and/or the at least one sensor are arranged above the die attach region and the at least one power device. The device package of the above-noted EXAMPLE includes sensor interconnects configured to connect to the at least one sensor and receive temperature signals from the at least one sensor. The device package of the above-noted EXAMPLE where the sensor interconnects extend outside of the assembly for external connection to a temperature measurement system. The device package of the above-noted EXAMPLE where the sensor interconnects extend to one of the signal contacts. The device package of the above-noted EXAMPLE where the at least one sensor receptacle comprises a sensor holding material portion within the assembly; and where the sensor holding material portion supports and/or contains the at least one sensor. The device package of the above-noted EXAMPLE where the sensor holding material portion comprises a gel, an isolation gel, a nonreflective gel, a nonreflective isolation gel, a painted gel, a painted isolation gel, a paint covered gel, and/or a paint covered isolation gel. The device package of the above-noted EXAMPLE where the assembly comprises a housing, a case, a molded housing, a molded case, an overmolded housing, and/or an overmolded case. The device package of the above-noted EXAMPLE comprising a power package, a semiconductor package, a power semiconductor package, a module, a power module, a power semiconductor module, an overmolded module, an overmolded power module, a case module, a discrete device, and/or a discrete power device. The device package of the above-noted EXAMPLE where the at least one power device comprises a power semiconductor device, a transistor device, a power transistor device, a diode, a power diode, a metal-oxide-semiconductor field-effect transistor (MOSFET) device, and/or an insulated-gate bipolar transistor (IGBT) device. The device package of the above-noted EXAMPLE where the at least one power device comprises a Silicon device, silicon carbide (SiC) device, and/or gallium nitride (GaN) device.

One EXAMPLE: a device package includes an assembly and the assembly comprises an assembly top surface. The device package in addition includes signal contacts arranged in and/or on the assembly. The package moreover includes power contacts arranged in and/or on the assembly. The package also includes at least one power device. The package further includes at least one sensor receptacle. The package in addition includes at least one sensor arranged in the at least one sensor receptacle. The package moreover includes where the at least one sensor receptacle and the at least one sensor are arranged above the at least one power device.

The above-noted EXAMPLE may further include any one or a combination of more than one of the following EXAMPLES: The device package of the above-noted EXAMPLE where the at least one sensor is arranged on an axis perpendicular to a top surface of the at least one power device. The device package of the above-noted EXAMPLE where the at least one sensor receptacle is arranged in and/or on the assembly top surface. The device package of the above-noted EXAMPLE where the at least one power device comprises power device sides that extend away from a top surface of the at least one power device; and where the at least one sensor is arranged between the power device sides of the at least one power device. The device package of the above-noted EXAMPLE where the at least one power device comprises a power device active area that relates to an area of detection of a junction temperature of the at least one power device; and where the at least one sensor is arranged in a middle section or middle of the power device active area. The device package of the above-noted EXAMPLE where the at least one sensor is configured to measure a temperature of the at least one power device, measure a temperature of a device junction of the at least one power device, and/or measure a junction temperature of the at least one power device. The device package of the above-noted EXAMPLE where the at least one sensor comprises a contactless sensor. The device package of the above-noted EXAMPLE where the at least one sensor is configured to measure a temperature of the at least one power device, measure a temperature of a device junction of the at least one power device, and/or measure a junction temperature of the at least one power device without contacting the at least one power device. The device package of the above-noted EXAMPLE where the at least one sensor is arranged above a middle section or middle area of the at least one power device. The device package of the above-noted EXAMPLE where the at least one sensor is arranged above the at least one power device along a vertical axis. The device package of the above-noted EXAMPLE where the at least one sensor is arranged above the at least one power device with a portion of the assembly therebetween. The device package of the above-noted EXAMPLE where the at least one sensor receptacle comprises a trench, a valley, a cavity, a channel, a groove, a pocket, an aperture, a hole, a location, a holder, a divot, a tunnel, and/or an arrangement. The device package of the above-noted EXAMPLE where the at least one power device comprises a plurality of the at least one power device. The device package of the above-noted EXAMPLE where the at least one sensor receptacle comprises a plurality of the at least one sensor receptacle; and where the at least one sensor comprises a plurality of the at least one sensor. The device package of the above-noted EXAMPLE where the at least one sensor receptacle comprises a circular shaped configuration, a square shape configuration, a rectangular shape configuration, a polygonal shape configuration, and/or an irregular shape configuration. The device package of the above-noted EXAMPLE where the at least one sensor receptacle is configured, arranged, and/or formed, during formation of the assembly. The device package of the above-noted EXAMPLE where the at least one sensor receptacle comprises a molded structure and/or a molded sensor receptacle. The device package of the above-noted EXAMPLE where the at least one sensor receptacle is configured, arranged, and/or formed, after formation of the assembly. The device package of the above-noted EXAMPLE where the at least one sensor receptacle comprises a machined structure and/or a machined sensor receptacle. The device package of the above-noted EXAMPLE where the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor. The device package of the above-noted EXAMPLE where the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor. The device package of the above-noted EXAMPLE where the at least one sensor is arranged on an external surface of the assembly. The device package of the above-noted EXAMPLE where the at least one sensor is not arranged on a component within the assembly. The device package of the above-noted EXAMPLE where the at least one sensor is self-calibrated. The device package of the above-noted EXAMPLE where the at least one sensor receptacle comprises sensor receptacle side surfaces and a sensor receptacle bottom surface; where the sensor receptacle side surfaces extend from the assembly top surface toward the at least one power device; and where at least one sensor is arranged on the sensor receptacle bottom surface. The device package of the above-noted EXAMPLE where the sensor receptacle bottom surface is arranged 1 mm 10 mm into the assembly, and/or below the assembly top surface. The device package of the above-noted EXAMPLE where the at least one sensor is attached to the sensor receptacle bottom surface by a glue, an adhesive, a potting material, a mold material, and/or a fill material. The device package of the above-noted EXAMPLE where the at least one sensor receptacle comprises an opening in the assembly top surface configured to allow insertion of the at least one sensor therein. The device package of the above-noted EXAMPLE where the signal contacts comprise one or more of a gate signal contact, a Kelvin-source signal contact, and/or a sensor contact. The device package of the above-noted EXAMPLE includes at least one power substrate, where the at least one power device is arranged on a top surface of the at least one power substrate, where the at least one sensor receptacle and/or the at least one sensor are arranged above the at least one power device and the at least one power substrate. The device package of the above-noted EXAMPLE includes at least one power substrate, where the at least one power substrate comprises a die attach region where the at least one power device is arranged on a top surface of the at least one power substrate; and where the at least one sensor receptacle and/or the at least one sensor are arranged above the die attach region and the at least one power device. The device package of the above-noted EXAMPLE includes sensor interconnects configured to connect to the at least one sensor and receive temperature signals from the at least one sensor. The device package of the above-noted EXAMPLE where the sensor interconnects extend outside of the assembly for external connection to a temperature measurement system. The device package of the above-noted EXAMPLE where the sensor interconnects extend to one of the signal contacts. The device package of the above-noted EXAMPLE where the at least one sensor receptacle comprises a sensor holding material portion within the assembly; and where the sensor holding material portion supports and/or contains the at least one sensor. The device package of the above-noted EXAMPLE where the sensor holding material portion comprises a gel, an isolation gel, a nonreflective gel, a nonreflective isolation gel, a painted gel, a painted isolation gel, a paint covered gel, and/or a paint covered isolation gel. The device package of the above-noted EXAMPLE where the assembly comprises a housing, a case, a molded housing, a molded case, an overmolded housing, and/or an overmolded case. The device package of the above-noted EXAMPLE comprising a power package, a semiconductor package, a power semiconductor package, a module, a power module, a power semiconductor module, an overmolded module, an overmolded power module, a case module, a discrete device, and/or a discrete power device. The device package of the above-noted EXAMPLE where the at least one power device comprises a power semiconductor device, a transistor device, a power transistor device, a diode, a power diode, a metal-oxide-semiconductor field-effect transistor (MOSFET) device, and/or an insulated-gate bipolar transistor (IGBT) device. The device package of the above-noted EXAMPLE where the at least one power device comprises a Silicon device, silicon carbide (SiC) device, and/or gallium nitride (GaN) device.

One EXAMPLE: a process includes providing an assembly comprising an assembly top surface. The process in addition includes arranging signal contacts in and/or on the assembly. The process moreover includes arranging power contacts in and/or on the assembly. The process also includes providing at least one power device. The process further includes providing at least one sensor receptacle. The process in addition includes arranging at least one sensor in the at least one sensor receptacle. The process moreover includes arranging the at least one sensor receptacle in and/or on the assembly top surface.

The above-noted EXAMPLE may further include any one or a combination of more than one of the following EXAMPLES: The process of the above-noted EXAMPLE includes arranging the at least one sensor on an axis perpendicular to a top surface of the at least one power device. The process of the above-noted EXAMPLE includes arranging the at least one sensor receptacle and the at least one sensor above the at least one power device. The process of the above-noted EXAMPLE where the at least one power device comprises power device sides that extend away from a top surface of the at least one power device; and where the at least one sensor is arranged between the power device sides of the at least one power device. The process of the above-noted EXAMPLE where the at least one power device comprises a power device active area that relates to an area of detection of a junction temperature of the at least one power device; and where the at least one sensor is arranged in a middle section or middle of the power device active area. The process of the above-noted EXAMPLE includes configuring the at least one sensor to measure a temperature of the at least one power device, measure a temperature of a device junction of the at least one power device, and/or measure a junction temperature of the at least one power device. The process of the above-noted EXAMPLE where the at least one sensor comprises a contactless sensor. The process of the above-noted EXAMPLE includes configuring the at least one sensor to measure a temperature of the at least one power device, measure a temperature of a device junction of the at least one power device, and/or measure a junction temperature of the at least one power device without contacting the at least one power device. The process of the above-noted EXAMPLE includes arranging the at least one sensor above a middle section or middle area of the at least one power device. The process of the above-noted EXAMPLE includes arranging the at least one sensor above the at least one power device along a vertical axis. The process of the above-noted EXAMPLE includes arranging the at least one sensor above the at least one power device with a portion of the assembly therebetween. The process of the above-noted EXAMPLE where the at least one sensor receptacle comprises a trench, a valley, a cavity, a channel, a groove, a pocket, an aperture, a hole, a location, a holder, a divot, a tunnel, and/or an arrangement. The process of the above-noted EXAMPLE where the at least one power device comprises a plurality of the at least one power device. The process of the above-noted EXAMPLE where the at least one sensor receptacle comprises a plurality of the at least one sensor receptacle; and where the at least one sensor comprises a plurality of the at least one sensor. The process of the above-noted EXAMPLE includes configuring the at least one sensor receptacle with a circular shaped configuration, a square shape configuration, a rectangular shape configuration, a polygonal shape configuration, and/or an irregular shape configuration. The process of the above-noted EXAMPLE includes configuring the at least one sensor receptacle during formation of the assembly. The process of the above-noted EXAMPLE includes molding the at least one sensor receptacle to form a molded structure and/or a molded sensor receptacle. The process of the above-noted EXAMPLE includes configuring the at least one sensor receptacle after formation of the assembly. The process of the above-noted EXAMPLE includes machining the at least one sensor receptacle to form a machined structure and/or a machined sensor receptacle. The process of the above-noted EXAMPLE where the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor. The process of the above-noted EXAMPLE where the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor. The process of the above-noted EXAMPLE includes arranging the at least one sensor on an external surface of the assembly. The process of the above-noted EXAMPLE where the at least one sensor is not arranged on a component within the assembly. The process of the above-noted EXAMPLE includes configuring the at least one sensor to be self-calibrated. The process of the above-noted EXAMPLE where the at least one sensor receptacle comprises sensor receptacle side surfaces and a sensor receptacle bottom surface; where the sensor receptacle side surfaces extend from the assembly top surface toward the at least one power device; and where at least one sensor is arranged on the sensor receptacle bottom surface. The process of the above-noted EXAMPLE where the sensor receptacle bottom surface is arranged 1 mm 10 mm into the assembly, and/or below the assembly top surface. The process of the above-noted EXAMPLE includes attaching the at least one sensor to the sensor receptacle bottom surface by a glue, an adhesive, a potting material, a mold material, and/or a fill material. The process of the above-noted EXAMPLE includes configuring the at least one sensor receptacle with an opening in the assembly top surface to allow insertion of the at least one sensor therein. The process of the above-noted EXAMPLE where the signal contacts comprise one or more of a gate signal contact, a Kelvin-source signal contact, and/or a sensor contact. The process of the above-noted EXAMPLE includes: providing at least one power substrate; arranging the at least one power device on a top surface of the at least one power substrate; and arranging the at least one sensor receptacle and/or the at least one sensor the at least one power device and the at least one power substrate. The process of the above-noted EXAMPLE includes providing at least one power substrate, where the at least one power substrate comprises a die attach region where the at least one power device is arranged on a top surface of the at least one power substrate; and where the at least one sensor receptacle and/or the at least one sensor are arranged above the die attach region and the at least one power device. The process of the above-noted EXAMPLE includes providing sensor interconnects and connecting the sensor interconnects to the at least one sensor and receive temperature signals from the at least one sensor. The process of the above-noted EXAMPLE where the sensor interconnects extend outside of the assembly for external connection to a temperature measurement system. The process of the above-noted EXAMPLE where the sensor interconnects extend to one of the signal contacts. The process of the above-noted EXAMPLE includes: configuring the at least one sensor receptacle with a sensor holding material portion within the assembly; and configuring the sensor holding material portion to support and/or contain the at least one sensor. The process of the above-noted EXAMPLE where the sensor holding material portion comprises a gel, an isolation gel, a nonreflective gel, a nonreflective isolation gel, a painted gel, a painted isolation gel, a paint covered gel, and/or a paint covered isolation gel. The process of the above-noted EXAMPLE includes configuring the assembly as a housing, a case, a molded housing, a molded case, an overmolded housing, and/or an overmolded case. The process of the above-noted EXAMPLE comprising a power package, a semiconductor package, a power semiconductor package, a module, a power module, a power semiconductor module, an overmolded module, an overmolded power module, a case module, a discrete device, and/or a discrete power device. The process of the above-noted EXAMPLE where the at least one power device comprises a power semiconductor device, a transistor device, a power transistor device, a diode, a power diode, a metal-oxide-semiconductor field-effect transistor (MOSFET) device, and/or an insulated-gate bipolar transistor (IGBT) device. The process of the above-noted EXAMPLE where the at least one power device comprises a Silicon device, silicon carbide (SiC) device, and/or gallium nitride (GaN) device.

One EXAMPLE: a process includes providing an assembly comprising an assembly top surface. The process in addition includes arranging signal contacts in and/or on the assembly. The process moreover includes arranging power contacts in and/or on the assembly. The process also includes providing at least one power device. The process further includes providing at least one sensor receptacle. The process in addition includes arranging at least one sensor in the at least one sensor receptacle. The process moreover includes arranging the at least one sensor on an axis perpendicular to a top surface of the at least one power device.

The above-noted EXAMPLE may further include any one or a combination of more than one of the following EXAMPLES: The process of the above-noted EXAMPLE includes arranging the at least one sensor receptacle in and/or on the assembly top surface. The process of the above-noted EXAMPLE includes arranging the at least one sensor receptacle and the at least one sensor above the at least one power device. The process of the above-noted EXAMPLE where the at least one power device comprises power device sides that extend away from a top surface of the at least one power device; and where the at least one sensor is arranged between the power device sides of the at least one power device. The process of the above-noted EXAMPLE where the at least one power device comprises a power device active area that relates to an area of detection of a junction temperature of the at least one power device; and where the at least one sensor is arranged in a middle section or middle of the power device active area. The process of the above-noted EXAMPLE includes configuring the at least one sensor to measure a temperature of the at least one power device, measure a temperature of a device junction of the at least one power device, and/or measure a junction temperature of the at least one power device. The process of the above-noted EXAMPLE where the at least one sensor comprises a contactless sensor. The process of the above-noted EXAMPLE includes configuring the at least one sensor to measure a temperature of the at least one power device, measure a temperature of a device junction of the at least one power device, and/or measure a junction temperature of the at least one power device without contacting the at least one power device. The process of the above-noted EXAMPLE includes arranging the at least one sensor above a middle section or middle area of the at least one power device. The process of the above-noted EXAMPLE includes arranging the at least one sensor above the at least one power device along a vertical axis. The process of the above-noted EXAMPLE includes arranging the at least one sensor above the at least one power device with a portion of the assembly therebetween. The process of the above-noted EXAMPLE where the at least one sensor receptacle comprises a trench, a valley, a cavity, a channel, a groove, a pocket, an aperture, a hole, a location, a holder, a divot, a tunnel, and/or an arrangement. The process of the above-noted EXAMPLE where the at least one power device comprises a plurality of the at least one power device. The process of the above-noted EXAMPLE where the at least one sensor receptacle comprises a plurality of the at least one sensor receptacle; and where the at least one sensor comprises a plurality of the at least one sensor. The process of the above-noted EXAMPLE includes configuring the at least one sensor receptacle with a circular shaped configuration, a square shape configuration, a rectangular shape configuration, a polygonal shape configuration, and/or an irregular shape configuration. The process of the above-noted EXAMPLE includes configuring the at least one sensor receptacle during formation of the assembly. The process of the above-noted EXAMPLE includes molding the at least one sensor receptacle to form a molded structure and/or a molded sensor receptacle. The process of the above-noted EXAMPLE includes configuring the at least one sensor receptacle after formation of the assembly. The process of the above-noted EXAMPLE includes machining the at least one sensor receptacle to form a machined structure and/or a machined sensor receptacle. The process of the above-noted EXAMPLE where the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor. The process of the above-noted EXAMPLE where the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor. The process of the above-noted EXAMPLE includes arranging the at least one sensor on an external surface of the assembly. The process of the above-noted EXAMPLE where the at least one sensor is not arranged on a component within the assembly. The process of the above-noted EXAMPLE includes configuring the at least one sensor to be self-calibrated. The process of the above-noted EXAMPLE where the at least one sensor receptacle comprises sensor receptacle side surfaces and a sensor receptacle bottom surface; where the sensor receptacle side surfaces extend from the assembly top surface toward the at least one power device; and where at least one sensor is arranged on the sensor receptacle bottom surface. The process of the above-noted EXAMPLE where the sensor receptacle bottom surface is arranged 1 mm 10 mm into the assembly, and/or below the assembly top surface. The process of the above-noted EXAMPLE includes attaching the at least one sensor to the sensor receptacle bottom surface by a glue, an adhesive, a potting material, a mold material, and/or a fill material. The process of the above-noted EXAMPLE includes configuring the at least one sensor receptacle with an opening in the assembly top surface to allow insertion of the at least one sensor therein. The process of the above-noted EXAMPLE where the signal contacts comprise one or more of a gate signal contact, a Kelvin-source signal contact, and/or a sensor contact. The process of the above-noted EXAMPLE includes: providing at least one power substrate; arranging the at least one power device on a top surface of the at least one power substrate; and arranging the at least one sensor receptacle and/or the at least one sensor the at least one power device and the at least one power substrate. The process of the above-noted EXAMPLE includes providing at least one power substrate, where the at least one power substrate comprises a die attach region where the at least one power device is arranged on a top surface of the at least one power substrate; and where the at least one sensor receptacle and/or the at least one sensor are arranged above the die attach region and the at least one power device. The process of the above-noted EXAMPLE includes providing sensor interconnects and connecting the sensor interconnects to the at least one sensor and receive temperature signals from the at least one sensor. The process of the above-noted EXAMPLE where the sensor interconnects extend outside of the assembly for external connection to a temperature measurement system. The process of the above-noted EXAMPLE where the sensor interconnects extend to one of the signal contacts. The process of the above-noted EXAMPLE includes: configuring the at least one sensor receptacle with a sensor holding material portion within the assembly; and configuring the sensor holding material portion to support and/or contain the at least one sensor. The process of the above-noted EXAMPLE where the sensor holding material portion comprises a gel, an isolation gel, a nonreflective gel, a nonreflective isolation gel, a painted gel, a painted isolation gel, a paint covered gel, and/or a paint covered isolation gel. The process of the above-noted EXAMPLE includes configuring the assembly as a housing, a case, a molded housing, a molded case, an overmolded housing, and/or an overmolded case. The process of the above-noted EXAMPLE comprising a power package, a semiconductor package, a power semiconductor package, a module, a power module, a power semiconductor module, an overmolded module, an overmolded power module, a case module, a discrete device, and/or a discrete power device. The process of the above-noted EXAMPLE where the at least one power device comprises a power semiconductor device, a transistor device, a power transistor device, a diode, a power diode, a metal-oxide-semiconductor field-effect transistor (MOSFET) device, and/or an insulated-gate bipolar transistor (IGBT) device. The process of the above-noted EXAMPLE where the at least one power device comprises a Silicon device, silicon carbide (SiC) device, and/or gallium nitride (GaN) device.

One EXAMPLE: a process includes providing an assembly comprising an assembly top surface. The process in addition includes arranging signal contacts in and/or on the assembly. The process moreover includes arranging power contacts in and/or on the assembly. The process also includes providing at least one power device. The process further includes providing at least one sensor receptacle. The process in addition includes arranging at least one sensor in the at least one sensor receptacle. The process moreover includes arranging the at least one sensor receptacle and the at least one sensor above the at least one power device.

The above-noted EXAMPLE may further include any one or a combination of more than one of the following EXAMPLES: The process of the above-noted EXAMPLE includes arranging the at least one sensor on an axis perpendicular to a top surface of the at least one power device. The process of the above-noted EXAMPLE includes arranging the at least one sensor receptacle in and/or on the assembly top surface. The process of the above-noted EXAMPLE where the at least one power device comprises power device sides that extend away from a top surface of the at least one power device; and where the at least one sensor is arranged between the power device sides of the at least one power device. The process of the above-noted EXAMPLE where the at least one power device comprises a power device active area that relates to an area of detection of a junction temperature of the at least one power device; and where the at least one sensor is arranged in a middle section or middle of the power device active area. The process of the above-noted EXAMPLE includes configuring the at least one sensor to measure a temperature of the at least one power device, measure a temperature of a device junction of the at least one power device, and/or measure a junction temperature of the at least one power device. The process of the above-noted EXAMPLE where the at least one sensor comprises a contactless sensor. The process of the above-noted EXAMPLE includes configuring the at least one sensor to measure a temperature of the at least one power device, measure a temperature of a device junction of the at least one power device, and/or measure a junction temperature of the at least one power device without contacting the at least one power device. The process of the above-noted EXAMPLE includes arranging the at least one sensor above a middle section or middle area of the at least one power device. The process of the above-noted EXAMPLE includes arranging the at least one sensor above the at least one power device along a vertical axis. The process of the above-noted EXAMPLE includes arranging the at least one sensor above the at least one power device with a portion of the assembly therebetween. The process of the above-noted EXAMPLE where the at least one sensor receptacle comprises a trench, a valley, a cavity, a channel, a groove, a pocket, an aperture, a hole, a location, a holder, a divot, a tunnel, and/or an arrangement. The process of the above-noted EXAMPLE where the at least one power device comprises a plurality of the at least one power device. The process of the above-noted EXAMPLE where the at least one sensor receptacle comprises a plurality of the at least one sensor receptacle; and where the at least one sensor comprises a plurality of the at least one sensor. The process of the above-noted EXAMPLE includes configuring the at least one sensor receptacle with a circular shaped configuration, a square shape configuration, a rectangular shape configuration, a polygonal shape configuration, and/or an irregular shape configuration. The process of the above-noted EXAMPLE includes configuring the at least one sensor receptacle during formation of the assembly. The process of the above-noted EXAMPLE includes molding the at least one sensor receptacle to form a molded structure and/or a molded sensor receptacle. The process of the above-noted EXAMPLE includes configuring the at least one sensor receptacle after formation of the assembly. The process of the above-noted EXAMPLE includes machining the at least one sensor receptacle to form a machined structure and/or a machined sensor receptacle. The process of the above-noted EXAMPLE where the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor. The process of the above-noted EXAMPLE where the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor. The process of the above-noted EXAMPLE includes arranging the at least one sensor on an external surface of the assembly. The process of the above-noted EXAMPLE where the at least one sensor is not arranged on a component within the assembly. The process of the above-noted EXAMPLE includes configuring the at least one sensor to be self-calibrated. The process of the above-noted EXAMPLE where the at least one sensor receptacle comprises sensor receptacle side surfaces and a sensor receptacle bottom surface; where the sensor receptacle side surfaces extend from the assembly top surface toward the at least one power device; and where at least one sensor is arranged on the sensor receptacle bottom surface. The process of the above-noted EXAMPLE where the sensor receptacle bottom surface is arranged 1 mm 10 mm into the assembly, and/or below the assembly top surface. The process of the above-noted EXAMPLE includes attaching the at least one sensor to the sensor receptacle bottom surface by a glue, an adhesive, a potting material, a mold material, and/or a fill material. The process of the above-noted EXAMPLE includes configuring the at least one sensor receptacle with an opening in the assembly top surface to allow insertion of the at least one sensor therein. The process of the above-noted EXAMPLE where the signal contacts comprise one or more of a gate signal contact, a Kelvin-source signal contact, and/or a sensor contact. The process of the above-noted EXAMPLE includes: providing at least one power substrate; arranging the at least one power device on a top surface of the at least one power substrate; and arranging the at least one sensor receptacle and/or the at least one sensor the at least one power device and the at least one power substrate. The process of the above-noted EXAMPLE includes providing at least one power substrate, where the at least one power substrate comprises a die attach region where the at least one power device is arranged on a top surface of the at least one power substrate; and where the at least one sensor receptacle and/or the at least one sensor are arranged above the die attach region and the at least one power device. The process of the above-noted EXAMPLE includes providing sensor interconnects and connecting the sensor interconnects to the at least one sensor and receive temperature signals from the at least one sensor. The process of the above-noted EXAMPLE where the sensor interconnects extend outside of the assembly for external connection to a temperature measurement system. The process of the above-noted EXAMPLE where the sensor interconnects extend to one of the signal contacts. The process of the above-noted EXAMPLE includes: configuring the at least one sensor receptacle with a sensor holding material portion within the assembly; and configuring the sensor holding material portion to support and/or contain the at least one sensor. The process of the above-noted EXAMPLE where the sensor holding material portion comprises a gel, an isolation gel, a nonreflective gel, a nonreflective isolation gel, a painted gel, a painted isolation gel, a paint covered gel, and/or a paint covered isolation gel. The process of the above-noted EXAMPLE includes configuring the assembly as a housing, a case, a molded housing, a molded case, an overmolded housing, and/or an overmolded case. The process of the above-noted EXAMPLE comprising a power package, a semiconductor package, a power semiconductor package, a module, a power module, a power semiconductor module, an overmolded module, an overmolded power module, a case module, a discrete device, and/or a discrete power device. The process of the above-noted EXAMPLE where the at least one power device comprises a power semiconductor device, a transistor device, a power transistor device, a diode, a power diode, a metal-oxide-semiconductor field-effect transistor (MOSFET) device, and/or an insulated-gate bipolar transistor (IGBT) device. The process of the above-noted EXAMPLE where the at least one power device comprises a Silicon device, silicon carbide (SiC) device, and/or gallium nitride (GaN) device.

Aspects of the disclosure have been described above with reference to the accompanying drawings, in which aspects of the disclosure are shown. It will be appreciated, however, that this disclosure may, however, be embodied in many different forms and should not be construed as limited to the aspects set forth above. Rather, these aspects are provided so that this disclosure will be thorough and complete, and will fully convey the scope of the disclosure to those skilled in the art. Additionally, the various aspects described may be implemented separately. Moreover, one or more the various aspects described may be combined. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

1. A device package comprising:
an assembly and the assembly comprises an assembly top surface;
signal contacts arranged in and/or on the assembly;
power contacts arranged in and/or on the assembly;
at least one power device;
at least one sensor receptacle; and
at least one sensor arranged in the at least one sensor receptacle,
wherein the at least one sensor receptacle is arranged in and/or on the assembly top surface.

2. The device package according to claim 1 wherein the at least one sensor is arranged on an axis perpendicular to a top surface of the at least one power device.

3. The device package according to claim 1 wherein the at least one sensor receptacle and the at least one sensor are arranged above the at least one power device.

4. The device package according to claim 1
wherein the at least one power device comprises power device sides that extend away from a top surface of the at least one power device; and
wherein the at least one sensor is arranged between the power device sides of the at least one power device.

5. The device package according to claim 1
wherein the at least one power device comprises a power device active area that relates to an area of detection of a junction temperature of the at least one power device; and
wherein the at least one sensor is arranged in a middle section or middle of the power device active area.

6. The device package according to claim 1 wherein the at least one sensor is configured to measure a temperature of the at least one power device, measure a temperature of a device junction of the at least one power device, and/or measure a junction temperature of the at least one power device.

7. The device package according to claim 1 wherein the at least one sensor comprises a contactless sensor.

8. The device package according to claim 1 wherein the at least one sensor is configured to measure a temperature of the at least one power device, measure a temperature of a device junction of the at least one power device, and/or measure a junction temperature of the at least one power device without contacting the at least one power device.

9. The device package according to claim 1 wherein the at least one sensor is arranged above a middle section or middle area of the at least one power device.

10. The device package according to claim 1 wherein the at least one sensor is arranged above the at least one power device along a vertical axis.

11. The device package according to claim 1 wherein the at least one sensor is arranged above the at least one power device with a portion of the assembly therebetween.

12. The device package according to claim 1 wherein the at least one sensor receptacle comprises a trench, a valley, a cavity, a channel, a groove, a pocket, an aperture, a hole, a location, a holder, a divot, a tunnel, and/or an arrangement.

13. The device package according to claim 1 wherein the at least one power device comprises a plurality of the at least one power device.

14. The device package according to claim 1
wherein the at least one sensor receptacle comprises a plurality of the at least one sensor receptacle; and
wherein the at least one sensor comprises a plurality of the at least one sensor.

15. The device package according to claim 1 wherein the at least one sensor receptacle comprises a circular shaped configuration, a square shape configuration, a rectangular shape configuration, a polygonal shape configuration, and/or an irregular shape configuration.

16. The device package according to claim 1 wherein the at least one sensor receptacle is configured, arranged, and/or formed, during formation of the assembly.

17. The device package according to claim 1 wherein the at least one sensor receptacle comprises a molded structure and/or a molded sensor receptacle.

18. The device package according to claim 1 wherein the at least one sensor receptacle is configured, arranged, and/or formed, after formation of the assembly.

19. The device package according to claim 1 wherein the at least one sensor receptacle comprises a machined structure and/or a machined sensor receptacle.

20. The device package according to claim 1 wherein the at least one sensor comprises a temperature sensor, a current sensor, a voltage sensor, a pressure sensor, a vibration sensor, a humidity sensor, a Hall effect sensor, a magnetic sensor, a strain sensor, a force sensor, and/or a pressure sensor.

21. The device package according to claim 1 wherein the at least one sensor comprises an infrared (IR) sensor, an infrared (IR) thermopile sensor, a thermocouple sensor, a negative temperature coefficient (NTC) sensor, a positive temperature coefficient (PTC) sensor, a bimetallic strip temperature sensor, a resistance temperature sensor, a silicon bandgap temperature sensor, and/or a thermistor.

22. (canceled)

23. The device package according to claim 1 wherein the at least one sensor is not arranged on a component within the assembly.

24. The device package according to claim 1 wherein the at least one sensor is self-calibrated.

25. The device package according to claim 1
wherein the at least one sensor receptacle comprises sensor receptacle side surfaces and a sensor receptacle bottom surface;
wherein the sensor receptacle side surfaces extend from the assembly top surface toward the at least one power device; and
wherein at least one sensor is arranged on the sensor receptacle bottom surface.

26. The device package according to claim 25 wherein the sensor receptacle bottom surface is arranged 1 mm-10 mm into the assembly, and/or below the assembly top surface.

27.-34. (canceled)

35. The device package according to claim 1
wherein the at least one sensor receptacle comprises a sensor holding material portion within the assembly; and
wherein the sensor holding material portion supports and/or contains the at least one sensor.

36. The device package according to claim 35 wherein the sensor holding material portion comprises a gel, an isolation gel, a nonreflective gel, a nonreflective isolation gel, a painted gel, a painted isolation gel, a paint covered gel, and/or a paint covered isolation gel.

37. The device package according to claim 1 wherein the assembly comprises a housing, a case, a molded housing, a molded case, an overmolded housing, and/or an overmolded case.

38. The device package according to claim 1 comprising a power package, a semiconductor package, a power semiconductor package, a module, a power module, a power semiconductor module, an overmolded module, an overmolded power module, a case module, a discrete device, and/or a discrete power device.

39.-40. (canceled)

41. A device package comprising:
an assembly and the assembly comprises an assembly top surface;
signal contacts arranged in and/or on the assembly;
power contacts arranged in and/or on the assembly;
at least one power device;
at least one sensor receptacle; and
at least one sensor arranged in the at least one sensor receptacle,
wherein the at least one sensor is arranged on an axis perpendicular to a top surface of the at least one power device.

42.-119. (canceled)

120. A process of manufacturing a device package comprising:
providing an assembly comprising an assembly top surface;
arranging signal contacts in and/or on the assembly;
arranging power contacts in and/or on the assembly;
providing at least one power device;
providing at least one sensor receptacle;
arranging at least one sensor in the at least one sensor receptacle; and
arranging the at least one sensor receptacle in and/or on the assembly top surface.

121.-239. (canceled)
